(19) United States
(12) Patent Application Publication
(10) Pub. No.: US 2026/0271192 A1
(43) Pub. Date: Sep. 10, 2026

(54) SEMICONDUCTOR DEVICE

(71) Applicant: FUJI ELECTRIC CO., LTD. M, Kawasaki-shi (JP)

(72) Inventors: Ryoichi KATO, Matsumoto-city (JP); Ryusuke KATO, Matsumoto-city (JP); Koji OSAKI, Matsumoto-city (JP)

(73) Assignee: FUJI ELECTRIC CO., LTD., Kawasaki-shi (JP)

(21) Appl. No.: 19/662,397

(22) Filed: Apr. 29, 2026

Related U.S. Application Data
(63) Continuation of application No. PCT/JP2025/006339, filed on Feb. 25, 2025.

(30) Foreign Application Priority Data
Mar. 22, 2024 (JP) 2024-046540

(51) Int. Cl. H05K 1/181; H05K 1/14; H10W 90/10

(52) U.S. Cl. CPC H05K 1/181; H05K 1/145; H10W 90/10; H05K 2201/042; H05K 2201/10272; H05K 2201/10318

(57) ABSTRACT

A semiconductor device includes: a first conductive plate connected to bottom surfaces of first semiconductor chips; a second conductive plate connected to bottom surfaces of second semiconductor chips; a third conductive plate connected to bottom surfaces of third and fourth semiconductor chips; a first external terminal connected to the first conductive plate; a second external terminal connected to top surfaces of the second semiconductor chips; a third external terminal connected to top surfaces of the third semiconductor chips; and a fourth external terminal connected to top surfaces of the first and fourth semiconductor chips. The first to third external terminals are disposed opposite to the fourth external terminal, and the first and second semiconductor chips are provided closer to the first and second external terminals than the third and fourth semiconductor chips.

### CROSS-REFERENCE TO RELATED APPLICATION

This application is a Continuation of PCT Application No. PCT/JP 2025/006339, filed on Feb. 25, 2025, and claims the priority of Japanese Patent Application No. 2024-046540, filed on Mar. 22, 2024, the content of which are incorporated herein by reference.

### TECHNICAL FIELD

This disclosure relates to a semiconductor device (a power semiconductor module).

### BACKGROUND ART

CN211957641U discloses a three-level semiconductor module.

JP2017-098421A discloses a semiconductor device in which a plurality of semiconductor units is electrically connected in parallel to each other with the use of a connecting device in order to reduce wiring inductance and achieve a higher rated current capacity. The connecting device includes a first connection unit and a second connection unit. The first connection unit is electrically connected to respective control terminals of the semiconductor units, and the second connection unit is electrically connected to respective main terminals of the semiconductor units.

### SUMMARY OF INVENTION

### Technical Problem

In CN211957641U, a positive terminal, a negative terminal, and an intermediate terminal are placed on the same side in a plan view. An output terminal is placed opposite to the positive terminal, the negative terminal, and the intermediate terminal across semiconductor chips. In terms of the arrangement of the semiconductor chips, semiconductor chips of an upper arm and a lower arm are disposed on a side where the output terminal is disposed, and a semiconductor chip of an intermediate arm is disposed on a side where the positive terminal, the negative terminal, and the intermediate terminal are disposed. Because of this, the inductance between the positive terminal and the negative terminal increases.

In view of the above problem, an object of this disclosure is to provide a three-level semiconductor device that can reduce the inductance between a positive terminal and a negative terminal.

### Solution to Problem

One aspect of this disclosure is a semiconductor device including: first to fourth semiconductor chips; a first conductive plate electrically connected to a bottom surface of the first semiconductor chip; a second conductive plate electrically connected to a bottom surface of the second semiconductor chip; a third conductive plate electrically connected to a bottom surface of each of the third and fourth semiconductor chips; a first external terminal connected to the first conductive plate; a second external terminal electrically connected to a top surface of the second semiconductor chip; a third external terminal electrically connected to a top surface of the third semiconductor chip; and a fourth external terminal electrically connected to a top surface of each of the first and fourth semiconductor chips. The first to third external terminals are disposed to be opposite to the fourth external terminal across the first to fourth semiconductor chips, and the first and second semiconductor chips are provided closer to the first and second external terminals than the third and fourth semiconductor chips.

The semiconductor device according to the one aspect of this disclosure may further include a wiring board including a first conductive layer electrically connecting the second conductive plate to the top surface of each of the first and fourth semiconductor chips, a second conductive layer electrically connected to the top surface of the second semiconductor chip and the second external terminal, a third conductive layer electrically connected to the top surface of the third semiconductor chip and the third external terminal, and an insulating layer disposed between the first conductive layer and the third conductive layer.

In the semiconductor device according to the one aspect of this disclosure, the first to fourth semiconductor chips may be electrically connected to the wiring board by at least one selected from pins, bumps, and solder.

In the semiconductor device according to the one aspect of this disclosure, the third conductive layer may include a plurality of third conductive layers, and the first conductive layer may be disposed between the third conductive layers via the insulating layer.

In the semiconductor device according to the one aspect of this disclosure, the first to fourth semiconductor chips may be disposed in a matrix form, the first semiconductor chip may be disposed diagonally to the fourth semiconductor chip, and the second semiconductor chip may be disposed diagonally to the third semiconductor chip.

In the semiconductor device according to the one aspect of this disclosure, each of the first to fourth semiconductor chips may include a plurality of semiconductor chips disposed to form a plurality of columns arranged side by side in a direction where the first to third external terminals are opposed to the fourth external terminal.

In the semiconductor device according to the one aspect of this disclosure, the first to fourth semiconductor chips may include gate electrodes on top surfaces of the first to fourth semiconductor chips respectively, and the respective gate electrodes may be disposed to face inward between the plurality of columns.

In the semiconductor device according to the one aspect of this disclosure, the wiring board may include a plurality of gate wiring foils electrically connected to the gate electrodes of the first to fourth semiconductor chips respectively, and the gate wiring foils may be electrically connected to the gate electrodes of the first to fourth semiconductor chips respectively by at least one selected from pins, bumps, and solder.

In the semiconductor device according to the one aspect of this disclosure, the wiring board may include a plurality of auxiliary control wiring foils electrically connected to the top surfaces of the first to fourth semiconductor chips respectively, and the auxiliary control wiring foils may be electrically connected to the top surfaces of the first to fourth semiconductor chips respectively by at least one selected from pins, bumps, and solder

In the semiconductor device according to the one aspect of this disclosure, the auxiliary control wiring foils may surround the gate wiring foils in a U-shape.

In the semiconductor device according to the one aspect of this disclosure, the gate wiring foils and the auxiliary control wiring foils may be provided on a top surface side of the wiring board relative to the first conductive layer, the second conductive layer, and the third conductive layer.

In the semiconductor device according to the one aspect of this disclosure, the first to fourth semiconductor chips may be disposed in a matrix form, the first semiconductor chip may be disposed diagonally to the third semiconductor chip, and the second semiconductor chip may be disposed diagonally to the fourth semiconductor chip.

In the semiconductor device according to the one aspect of this disclosure, the second conductive plate may be electrically connected to each of the top surfaces of the first and fourth semiconductor chips by a wire, the top surface of the second semiconductor chip may be electrically connected to the second external terminal by a wire, and the top surface of the third semiconductor chip may be electrically connected to the third external terminal by a wire.

In the semiconductor device according to the one aspect of this disclosure, the first and second semiconductor chips may be provided closer to the first to third external terminals than the third and fourth semiconductor chips.

Note that the summary of the invention does not describe all necessary features of this disclosure. Subcombinations of these features can also be included in the invention.

### BRIEF DESCRIPTION OF DRAWINGS

FIG. 1 is an equivalent circuit diagram of a semiconductor device according to a first embodiment;

FIG. 2 is a side view of the semiconductor device according to the first embodiment;

FIG. 3 is a plan view of the semiconductor device according to the first embodiment;

FIG. 4 is a plan view illustrating the semiconductor device according to the first embodiment without a wiring board;

FIG. 5 is a plan view of a conductive layer as the first layer from the top of the wiring board of the semiconductor device according to the first embodiment;

FIG. 6 is a plan view of a conductive layer as the second layer from the top of the wiring board of the semiconductor device according to the first embodiment;

FIG. 7 is a plan view of a conductive layer as the third layer from the top of the wiring board of the semiconductor device according to the first embodiment;

FIG. 8 is a plan view of a conductive layer as the fourth layer from the top of the wiring board of the semiconductor device according to the first embodiment;

FIG. 9 is a plan view illustrating a current path between a positive terminal and a negative terminal without the wiring board in the semiconductor device according to the first embodiment;

FIG. 10 is a plan view illustrating a current path between the positive terminal and the negative terminal on the conductive layer as the second layer from the top of the wiring board in the semiconductor device according to the first embodiment;

FIG. 11 is a plan view illustrating a current path between the positive terminal and the negative terminal on the conductive layer as the third layer from the top of the wiring board in the semiconductor device according to the first embodiment;

FIG. 12 is a plan view illustrating a current path between the positive terminal and an intermediate terminal without the wiring board in the semiconductor device according to the first embodiment;

FIG. 13 is a plan view illustrating a current path between the positive terminal and the intermediate terminal on the conductive layer as the second layer from the top of the wiring board in the semiconductor device according to the first embodiment;

FIG. 14 is a plan view illustrating a current path between the positive terminal and the intermediate terminal on the conductive layer as the third layer from the top of the wiring board in the semiconductor device according to the first embodiment;

FIG. 15 is a plan view illustrating a current path between the negative terminal and the intermediate terminal without the wiring board in the semiconductor device according to the first embodiment;

FIG. 16 is a plan view illustrating a current path between the negative terminal and the intermediate terminal on the conductive layer as the second layer from the top of the wiring board in the semiconductor device according to the first embodiment;

FIG. 17 is a plan view illustrating a current path between the negative terminal and the intermediate terminal on the conductive layer as the third layer from the top of the wiring board in the semiconductor device according to the first embodiment;

FIG. 18 is a plan view of a semiconductor device according to a comparative example;

FIG. 19 is a plan view illustrating a current path between a positive terminal and a negative terminal in the semiconductor device according to the comparative example;

FIG. 20 is a plan view illustrating a current path between the positive terminal and an intermediate terminal in the semiconductor device according to the comparative example;

FIG. 21 is a plan view illustrating a current path between the negative terminal and the intermediate terminal in the semiconductor device according to the comparative example;

FIG. 22 is a table exhibiting simulation results of inductance values in Example and Comparative Examples A, B;

FIG. 23 is a plan view of a semiconductor device according to a second embodiment;

FIG. 24 is a plan view of a semiconductor device according to a third embodiment;

FIG. 25 is a plan view illustrating a semiconductor device according to a fourth embodiment without a wiring board;

FIG. 26 is a plan view of the semiconductor device according to the fourth embodiment;

FIG. 27 is a plan view of a conductive layer as the second layer from the top of the wiring board of the semiconductor device according to the fourth embodiment; and

FIG. 28 is a plan view of a conductive layer as the third layer from the top of the wiring board of the semiconductor device according to the fourth embodiment.

### DESCRIPTION OF EMBODIMENTS

With reference to the drawings, the following describes first to fourth embodiments of this disclosure.

In the drawings to be referred to in the following description, identical or similar parts have identical or similar reference signs. It should be noted that the drawings are schematic, and the relationship between thickness and flat dimension, the ratio between layer thicknesses, and the like are different from actual ones. Accordingly, a specific thickness or dimension should be determined in consideration of the following description. Besides, it is needless to say that different drawings include parts with different dimensional relationships or ratios.

The definitions of directions such as “up,” “down,” “up-down,” “right,” “left,” “right-left,” and so on are merely definitions for convenience of the description and do not restrict the technical idea of this disclosure. For example, when a target is rotated by 90° and observed, the “up-down direction” is replaced with the “right-left direction,” and when the target is rotated by 180° and observed, the top and bottom are upside down.

A “top surface” and a “bottom surface” may be replaced with a “front surface” and a “back surface,” respectively. Besides, a “first principal surface” and a “second principal surface” of each member are principal surfaces opposed to each other, and when the “first principal surface” is a top surface, the “second principal surface” is a bottom surface, for example. In addition, the “first principal surface” and the “second principal surface” may be read as “one principal surface” and “the other principal surface,” respectively.

In the following description, a “first main electrode” of a semiconductor chip indicates an electrode via which a principal current flows in or out of the semiconductor chip. In a case where the semiconductor chip is a field effect transistor (FET) or a static induction transistor (SIT), the “first main electrode” indicates either a source electrode or a drain electrode, in a case where the semiconductor chip is an insulated gate bipolar transistor (IGBT), the “first main electrode” indicates either an emitter electrode or a collector electrode, and in a case where the semiconductor chip is an electrostatic induction (SI) thyristor or a gate turnoff (GTO) thyristor, the “first main electrode” indicates either an anode electrode or a cathode electrode. In a case where the semiconductor chip is an FET or an SIT, a “second main electrode” of the semiconductor chip indicates either a source electrode or a drain electrode that is not the first main electrode, in a case where the semiconductor chip is an IGBT, the “second main electrode” indicates either an emitter electrode or a collector electrode that is not the first main electrode, and in a case where the semiconductor chip is an SI thyristor or a GTO thyristor, the “second main electrode” indicates either an anode electrode or a cathode electrode that is not the first main electrode. That is, when the “first main electrode” of the semiconductor chip is a source electrode, the “second main electrode” indicates a drain electrode. When the “first main electrode” of the semiconductor chip is an emitter electrode, the “second main electrode” indicates a collector electrode. When the “first main electrode” of the semiconductor chip is an anode electrode, the “second main electrode” indicates a cathode electrode.

### First Embodiment

### Circuit of Semiconductor Device

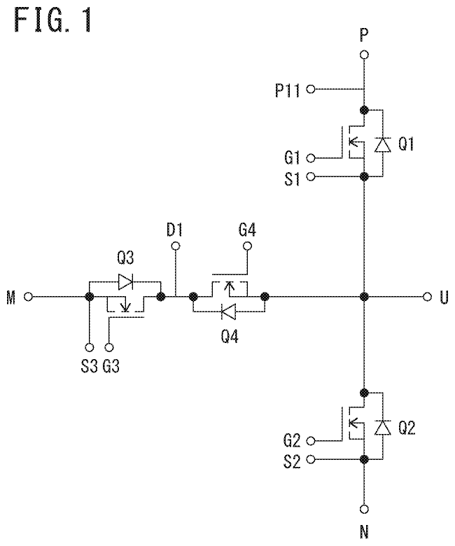

A semiconductor device according to a first embodiment is a power semiconductor module constituting a circuit corresponding to one phase (i.e., a three-level circuit) of a three-level power conversion device (three-level inverter) circuit. FIG. 1 illustrates an example of an equivalent circuit of the semiconductor device according to the first embodiment. As illustrated in FIG. 1, the semiconductor device according to the first embodiment includes an upper arm Q1, a lower arm Q2, an intermediate arm Q3 on the upstream side, an intermediate arm Q4 on the downstream side, a positive terminal P, a negative terminal N, an intermediate terminal M, and an output terminal U. The upper arm Q1, the lower arm Q2, and the intermediate arms Q3, Q4 each include a transistor and a freewheeling diode (FWD) connected in anti-parallel with the transistor.

A drain of the transistor of the upper arm Q1 is connected to the positive terminal P. The output terminal U and a drain of the transistor of the lower arm Q2 are connected to a source of the transistor of the upper arm Q1. The negative terminal N is connected to a source of the transistor of the lower arm Q2. A source of the transistor of the intermediate arm Q3 is connected to the intermediate terminal M. A drain of the transistor of the intermediate arm Q4 is connected to a drain of the transistor of the intermediate arm Q3. The output terminal U, a source of the transistor of the upper arm Q1, and a drain of the transistor of the lower arm Q2 are connected to a source of the transistor of the intermediate arm Q4.

A potential detection terminal P11 is connected between the positive terminal P and the drain of the transistor of the upper arm Q1. A potential detection terminal D1 is connected between the drain of the transistor of the intermediate arm Q3 and the drain of the transistor of the intermediate arm Q4.

### Structure of Semiconductor Device

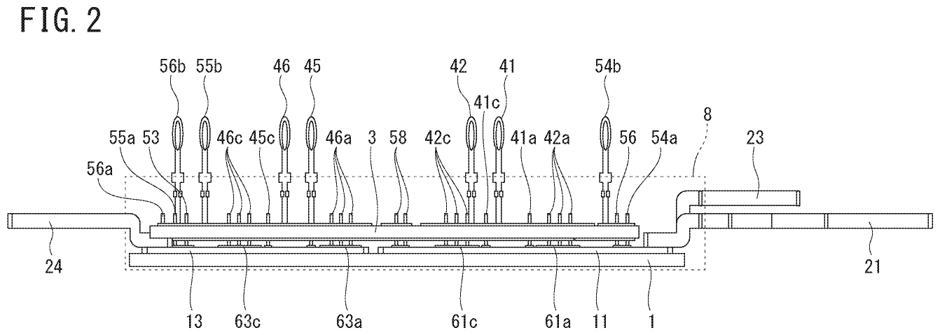

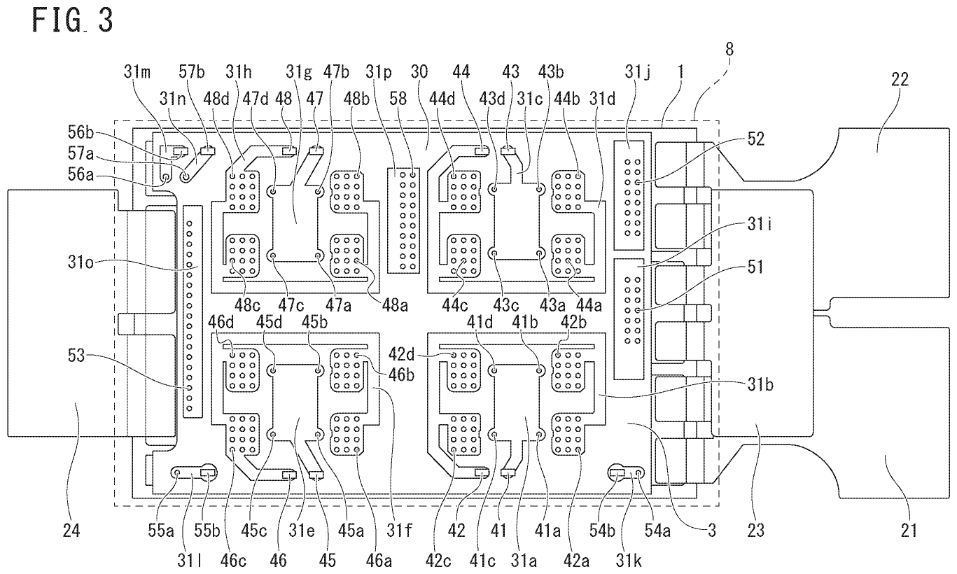

FIG. 2 is a side view of the semiconductor device according to the first embodiment, and FIG. 3 is a plan view of the semiconductor device according to the first embodiment. As illustrated in FIG. 2 and FIG. 3, the semiconductor device according to the first embodiment includes an insulating substrate 1, a wiring board 3 provided above the insulating substrate 1, and a positive terminal 21, a negative terminal 22, an intermediate terminal 23, and an output terminal 24 provided on the top surface side of the insulating substrate 1.

Pin-shaped conductive members (hereinafter referred to as “pins”) 41a to 41d, 42a to 42d, 43a to 43d, 44a to 44d, 45a to 45d, 46a to 46d, 47a to 47d, 48a to 48d, 51 to 53, 54a, 55a, 56a, 57a, 58, and control terminals 41 to 48, 54b, 55b, 56b, 57b are vertically fitted by pressing in the wiring board 3.

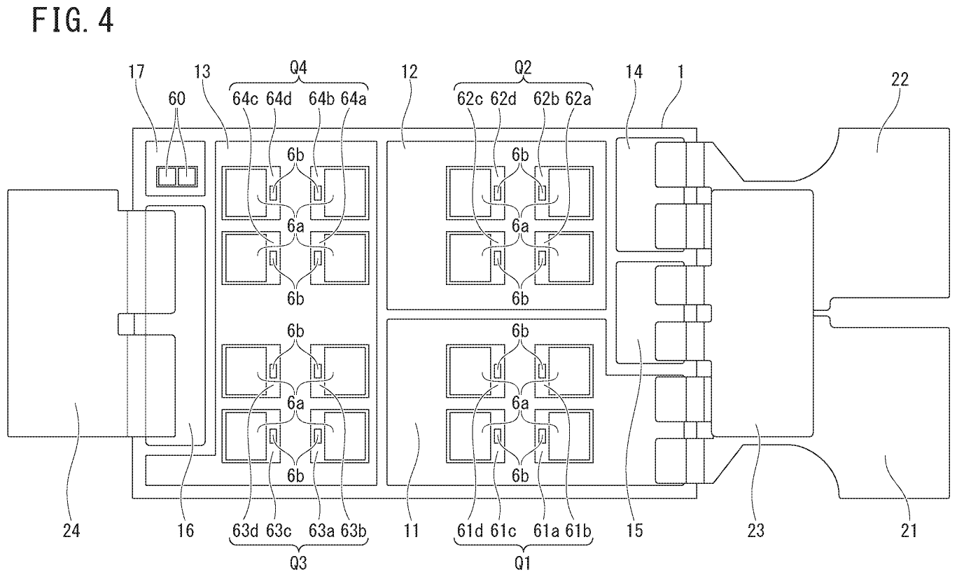

FIG. 4 illustrates a planar layout of the semiconductor device according to the first embodiment illustrated in FIG. 3 without the wiring board 3. The insulating substrate 1 has a generally rectangular plane pattern. The insulating substrate 1 is made of an insulation material and is constituted by a resin substrate made of liquid crystalline polymer (LCP), epoxy resin, or the like, for example. The insulating substrate 1 may be constituted by a ceramics substrate made of aluminum oxide (Al₂O₃), aluminum nitride (AlN), silicon nitride (Si₃N₄), boron nitride (BN), or the like.

Conductive plates (conductive foils) 11 to 17 forming a circuit pattern are provided on the top surface side of the insulating substrate 1. The conductive plates 11 to 17 are made of a conductive material such as copper (Cu), Cu alloy, aluminum (Al), or Al alloy, for example. Note that a conductive plate (a heat dissipation plate) may be provided on the bottom surface of the insulating substrate 1, or the insulating substrate 1, the conductive plates 11 to 17, and the conductive plate (the heat dissipation plate) may be constituted by an insulating circuit board such as a direct copper bonding (DCB) substrate or an active metal brazing (AMD) substrate.

One end of the positive terminal 21 is bonded to the top surface side of the conductive plate 11 via a bonding material (not illustrated) such as solder or a sintered material and electrically connected thereto. One end of the negative terminal 22 is bonded to the top surface side of the conductive plate 14 via a bonding material (not illustrated) such as solder or a sintered material and electrically connected thereto. One end of the intermediate terminal 23 is bonded to the top surface side of the conductive plate 15 via a bonding material (not illustrated) such as solder or a sintered material and electrically connected thereto. One end of the output terminal 24 is bonded to the top surface side of the conductive plate 16 via a bonding material (not illustrated) such as solder or a sintered material and electrically connected thereto.

The positive terminal 21, the negative terminal 22, the intermediate terminal 23, and the output terminal 24 correspond to the positive terminal P, the negative terminal N, the intermediate terminal M, and the output terminal U illustrated in FIG. 1. The positive terminal 21, the negative terminal 22, the intermediate terminal 23, and the output terminal 24 are external terminals connectable to external members such as a capacitor or a motor and serve as main terminals through which main current flows. The positive terminal 21, the negative terminal 22, the intermediate terminal 23, and the output terminal 24 are made of a conductive material such as copper (Cu), Cu alloy, aluminum (Al), or Al alloy, for example. The positive terminal 21, the negative terminal 22, the intermediate terminal 23, and the output terminal 24 have a flat plate shape, for example, and include L-shaped bent portions.

The positive terminal 21, the negative terminal 22, and the intermediate terminal 23 are provided on one end side of a generally rectangular shape formed by the plane pattern of the insulating substrate 1, in its longitudinal direction. The reason why the positive terminal 21, the negative terminal 22, and the intermediate terminal 23 are provided collectively in the same direction is to connect the positive terminal 21, the negative terminal 22, and the intermediate terminal 23 to the capacitor and therefore to achieve easy connection with the capacitor and reduce the inductance between the module and the capacitor. From the viewpoint of the creepage distance of insulation, the positive terminal 21, the intermediate terminal 23, and the negative terminal 22 are arranged in this order in the short direction of the generally rectangular shape formed by the plane pattern of the insulating substrate 1. That is, when the intermediate terminal 23 as an intermediate potential is disposed midmost, the creepage distance of insulation is shortened, thereby making it possible to shorten the distance between terminals.

In the meantime, the output terminal 24 is provided on the other end side of the generally rectangular shape formed by the plane pattern of the insulating substrate 1 in the longitudinal direction, which is opposite to the positive terminal 21, the negative terminal 22, and the intermediate terminal 23 across semiconductor chips 61a to 61d, 62a to 62d, 63a to 63d, 64a to 64d. The reason why the output terminal 24 is disposed on the opposite side to the positive terminal 21, the negative terminal 22, and the intermediate terminal 23 is as follows. That is, when the output terminal 24 is disposed to project in a direction where there is no capacitor component connected to the positive terminal 21, the negative terminal 22, and the intermediate terminal 23, the output terminal 24 is easily connected to a motor.

The semiconductor chips 61a to 61d, 62a to 62d, 63a to 63d, 64a to 64d are provided on the top surface sides of the conductive plates 11 to 13 via a bonding material (not illustrated) such as solder or a sintered material. The semiconductor chips 61a to 61d correspond to the upper arm Q1 illustrated in FIG. 1. The semiconductor chips 62a to 62d correspond to the lower arm Q2 illustrated in FIG. 1. The semiconductor chips 63a to 63d correspond to the intermediate arm Q3 illustrated in FIG. 1. The semiconductor chips 64a to 64d correspond to the intermediate arm Q4 illustrated in FIG. 1. Note that the semiconductor chips 61a to 61d may be transistors incorporating FWDS, which constitute the upper arm Q1 illustrated in FIG. 1. The semiconductor chips 62a to 62d may be transistors incorporating FWDS, which constitute the lower arm Q2 illustrated in FIG. 1. The semiconductor chips 63a to 63d may be transistors incorporating FWDS, which constitute the intermediate arm Q3 illustrated in FIG. 1. The semiconductor chips 64a to 64d may be transistors incorporating FWDS, which constitute the intermediate arm Q4 illustrated in FIG. 1.

In the semiconductor device according to the first embodiment to be described herein, the semiconductor chips 61a to 61d, 62a to 62d, 63a to 63d, 64a to 64d are metal oxide semiconductor field effect transistors (MOSFET). Each of the semiconductor chips 61a to 61d, 62a to 62d, 63a to 63d, 64a to 64d includes a first main electrode (source electrode) 6a and a gate electrode 6b on its top surface side and a second main electrode (drain electrode) (not illustrated) on its bottom surface side.

Note that each of the semiconductor chips 61a to 61d, 62a to 62d, 63a to 63d, 64a to 64d may be an insulated gate bipolar transistor (IGBT), a reverse conducting insulated gate bipolar transistor (RC-IGBT) in which a diode is connected in anti-parallel with an IGBT, an electrostatic induction (SI) thyristor, a gate turnoff (GTO) thyristor, or the like. The number of semiconductor chips 61a to 61d, 62a to 62d, 63a to 63d, 64a to 64d is not particularly limited. Each of the transistors and the diodes of the upper arm Q1, the lower arm Q2, and the intermediate arms Q3, Q4 illustrated in FIG. 1 may be constituted by an individual semiconductor chip.

A semiconductor substrate of each of the semiconductor chips 61a to 61d, 62a to 62d, 63a to 63d, 64a to 64d is made of silicon (Si), silicon carbide (SiC), gallium nitride (GaN), gallium oxide (Ga₂O₃), diamond (C), or the like, for example.

The upper arm Q1 includes a plurality of semiconductor chips 61a to 61d, the lower arm Q2 includes a plurality of semiconductor chips 62a to 62d, the intermediate arm Q3 includes a plurality of semiconductor chips 63a to 63d, and the intermediate arm Q4 includes a plurality of semiconductor chips 64a to 64d. They form a plurality of columns arranged in a direction (the right-left direction in FIG. 3) where the positive terminal 21, the negative terminal 22, and the intermediate terminal 23 are opposite to the output terminal 24. The gate electrode 6b of each of the semiconductor chips 61a to 61d, 62a to 62d, 63a to 63d, 64a to 64d is disposed to face inward between the plurality of columns.

As illustrated in FIG. 4, the drain electrodes (not illustrated) on the bottom surface sides of the semiconductor chips 61a to 61d are bonded to the top surface of the conductive plate 11 via a bonding material (not illustrated) such as solder or a sintered material and electrically connected thereto. The drain electrodes (not illustrated) on the bottom surface sides of the semiconductor chips 62a to 62d are bonded to the top surface of the conductive plate 12 via a bonding material (not illustrated) such as solder or a sintered material and electrically connected thereto. The drain electrodes (not illustrated) on the bottom surface sides of the semiconductor chips 63a to 63d, 64a to 64d are bonded to the top surface of the conductive plate 13 via a bonding material (not illustrated) such as solder or a sintered material and electrically connected thereto.

A semiconductor chip 60 constituting a temperature detector diode is provided on the top surface side of the conductive plate 17 via a bonding material (not illustrated) such as solder or a sintered material and is electrically connected thereto.

In the semiconductor device according to the first embodiment, the semiconductor chips 61a to 61d, 62a to 62d are disposed on the side where the positive terminal 21, the negative terminal 22, and the intermediate terminal 23 are provided. The semiconductor chips 63a to 63d, 64a to 64d are disposed on the side where the output terminal 24 is provided. The semiconductor chips 61a to 61d, 62a to 62d, 63a to 63d, 64a to 64d are placed in a matrix form. The semiconductor chips 61a to 61d are disposed diagonally to the semiconductor chips 64a to 64d. The semiconductor chips 62a to 62d are disposed diagonally to the semiconductor chips 63a to 63d.

The wiring board 3 illustrated in FIG. 2 and FIG. 3 has a generally rectangular plane pattern. The wiring board 3 is a multilayer wiring board having a plurality of conductive layers. An insulating layer 30 is provided between the conductive layers of the wiring board 3. The uppermost conductive layer and the lowermost conductive layer of the wiring board 3 are exposed from the insulating layer 30. The wiring board 3 is provided above the semiconductor chips 61a to 61d, 62a to 62d, 63a to 63d, 64a to 64d. The wiring board 3 is electrically connected to the conductive plates 11 to 17 and the semiconductor chips 61a to 61d, 62a to 62d, 63a to 63d, 64a to 64d, via the pins 41a to 41d, 42a to 42d, 43a to 43d, 44a to 44d, 45a to 45d, 46a to 46d, 47a to 47d, 48a to 48d, 51 to 53, 54a, 55a, 56a, 57a, 58.

Note that the wiring board 3 may be bonded to and electrically connected to the conductive plates 11 to 17 and the semiconductor chips 61a to 61d, 62a to 62d, 63a to 63d, 64a to 64d via solder without the use of the pins 41a to 41d, 42a to 42d, 43a to 43d, 44a to 44d, 45a to 45d, 46a to 46d, 47a to 47d, 48a to 48d, 51 to 53, 54a, 55a, 56a, 57a, 58. The wiring board 3 may be bonded to and electrically connected to the conductive plates 11 to 17 and the semiconductor chips 61a to 61d, 62a to 62d, 63a to 63d, 64a to 64d via bumps.

The control terminals 41 to 48, 54b, 55b, 56b, 57b are provided along two long sides of the rectangular plane pattern of the wiring board 3 so as to vertically project from the top surface side of the wiring board 3. FIG. 2 and FIG. 3 illustrate a case where the control terminals 41 to 48, 54b, 55b, 56b, 57b are press-fit pins, but the shapes of the control terminals 41 to 48, 54b, 55b, 56b, 57b are not particularly limited.

The control terminal 41 corresponds to a gate terminal G1 of the transistor of the upper arm Q1 illustrated in FIG. 1. The control terminal 42 corresponds to an auxiliary source terminal S1 of the transistor of the upper arm Q1 illustrated in FIG. 1. The control terminal 43 corresponds to a gate terminal G2 of the transistor of the lower arm Q2 illustrated in FIG. 1. The control terminal 44 corresponds to an auxiliary source terminal S2 of the transistor of the lower arm Q2 illustrated in FIG. 1. The control terminal 45 corresponds to a gate terminal G3 of the transistor of the intermediate arm Q3 illustrated in FIG. 1. The control terminal 46 corresponds to an auxiliary source terminal S3 of the transistor of the intermediate arm Q3 illustrated in FIG. 1. The control terminal 47 corresponds to a gate terminal G4 of the transistor of the intermediate arm Q4 illustrated in FIG. 1. The control terminal 48 corresponds to an auxiliary source terminal S4 of the transistor of the intermediate arm Q4 illustrated in FIG. 1. The control terminal 54b corresponds to the potential detection terminal P11 illustrated in FIG. 1. The control terminal 55b corresponds to the potential detection terminal D1 illustrated in FIG. 1. The control terminals 56b, 57b correspond to an anode terminal and a cathode terminal of a temperature detector diode, although not illustrated in FIG. 1.

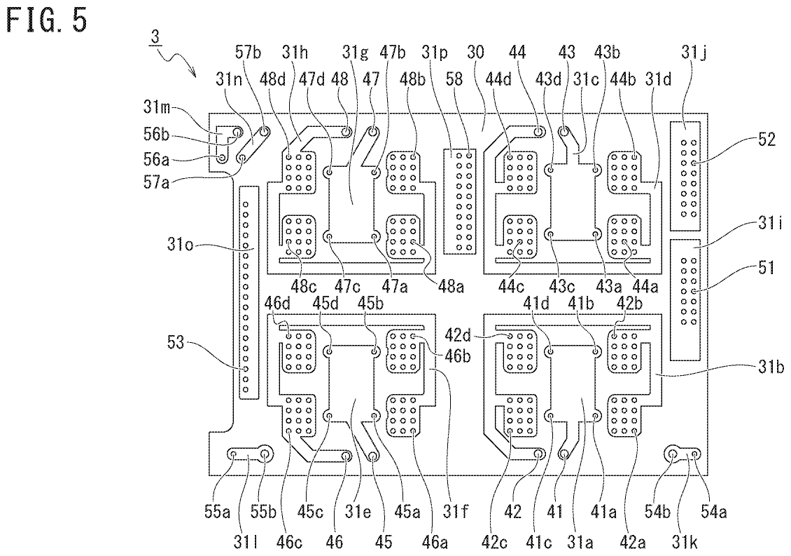

FIG. 5 is a plan view illustrating the wiring board 3 in an extracted manner. The wiring board 3 includes an insulating layer 30 having a generally rectangular plane pattern, and conductive layers 31a to 31p provided on the top surface side of the insulating layer 30. Each of the conductive layers 31a to 31h has through-holes that reach the bottom surface of the wiring board 3. The conductive layers 31a, 31c, 31e, 31g are gate wiring foils electrically connected to corresponding gate electrodes 6b on the top surface sides of the semiconductor chips 61a to 61d, 62a to 62d, 63a to 63d, 64a to 64d via at least one selected from pins, bumps, and solder. The conductive layers 31b, 31d, 31f, 31h are auxiliary control wiring foils electrically connected to corresponding source electrodes 6a on the top surface sides of the semiconductor chips 61a to 61d, 62a to 62d, 63a to 63d, 64a to 64d via at least one selected from pins, bumps, and solder.

The pins 41a to 41d extending vertically are fitted by pressing in the through-holes provided in the conductive layer 31a and electrically connected thereto. The pins 41a to 41d have bottom ends bonded to corresponding gate electrodes 6b of the semiconductor chips 61a to 61d via a bonding material (not illustrated) such as solder or a sintered material and electrically connected thereto. The control terminal 41 extending vertically is fitted by pressing in another through-hole provided in the conductive layer 31a and electrically connected thereto.

The conductive layer 31b has a U-shaped plane pattern to surround the conductive layer 31a. The pins 42a to 42d extending vertically are fitted by pressing in the through-holes provided in the conductive layer 31b and electrically connected thereto. The pins 42a to 42d have bottom ends bonded to corresponding source electrodes 6a of the semiconductor chips 61a to 61d via a bonding material (not illustrated) such as solder or a sintered material and electrically connected thereto. The control terminal 42 extending vertically is fitted by pressing in another through-hole provided in the conductive layer 31b and electrically connected thereto.

The pins 43a to 43d extending vertically are fitted by pressing in the through-holes provided in the conductive layer 31c and electrically connected thereto. The pins 43a to 43d have bottom ends bonded to corresponding gate electrodes 6b of the semiconductor chips 62a to 62d via a bonding material (not illustrated) such as solder or a sintered material and electrically connected thereto. The control terminal 43 extending vertically is fitted by pressing in another through-hole provided in the conductive layer 31c and electrically connected thereto.

The conductive layer 31d has a U-shaped plane pattern to surround the conductive layer 31c. The pins 44a to 44d extending vertically are fitted by pressing in the through-holes provided in the conductive layer 31d and electrically connected thereto. The pins 44a to 44d have bottom ends bonded to corresponding source electrodes 6a of the semiconductor chips 62a to 62d via a bonding material (not illustrated) such as solder or a sintered material and electrically connected thereto. The control terminal 44 extending vertically is fitted by pressing in another through-hole provided in the conductive layer 31d and electrically connected thereto.

The pins 45a to 45d extending vertically are fitted by pressing in the through-holes provided in the conductive layer 31e and electrically connected thereto. The pins 45a to 45d have bottom ends bonded to corresponding gate electrodes 6b of the semiconductor chips 63a to 63d via a bonding material (not illustrated) such as solder or a sintered material and electrically connected thereto. The control terminal 45 extending vertically is fitted by pressing in another through-hole provided in the conductive layer 31e and electrically connected thereto.

The conductive layer 31f has a U-shaped plane pattern to surround the conductive layer 31e. The pins 46a to 46d extending vertically are fitted by pressing in the through-holes provided in the conductive layer 31f and electrically connected thereto. The pins 46a to 46d have bottom ends bonded to corresponding source electrodes 6a of the semiconductor chips 63a to 63d via a bonding material (not illustrated) such as solder or a sintered material and electrically connected thereto. The control terminal 46 extending vertically is fitted by pressing in another through-hole provided in the conductive layer 31f and electrically connected thereto.

The pins 47a to 47d extending vertically are fitted by pressing in the through-holes provided in the conductive layer 31g and electrically connected thereto. The pins 47a to 47d have bottom ends bonded to corresponding gate electrodes 6b of the semiconductor chips 64a to 64d via a bonding material (not illustrated) such as solder or a sintered material and electrically connected thereto. The control terminal 47 extending vertically is fitted by pressing in another through-hole provided in the conductive layer 31g and electrically connected thereto.

The conductive layer 31h has a U-shaped plane pattern to surround the conductive layer 31g. The pins 48a to 48d extending vertically are fitted by pressing in the through-holes provided in the conductive layer 31h and electrically connected thereto. The pins 48a to 48d have bottom ends bonded to corresponding source electrodes 6a of the semiconductor chips 64a to 64d via a bonding material (not illustrated) such as solder or a sintered material and electrically connected thereto. The control terminal 48 extending vertically is fitted by pressing in another through-hole provided in the conductive layer 31h and electrically connected thereto.

The pins 51 extending vertically are fitted by pressing in the through-holes provided in the conductive layer 31i and electrically connected thereto. The pins 51 have bottom ends bonded to the conductive plate 15 via a bonding material (not illustrated) such as solder or a sintered material and electrically connected thereto. The pins 52 extending vertically are fitted by pressing in the through-holes provided in the conductive layer 31j and electrically connected thereto. The pins 52 have bottom ends bonded to the conductive plate 14 via a bonding material (not illustrated) such as solder or a sintered material and electrically connected thereto.

The pin 54a extending vertically is fitted by pressing in the through-hole provided in the conductive layer 31k and electrically connected thereto. The pin 54a has a bottom end bonded to the conductive plate 11 via a bonding material (not illustrated) such as solder or a sintered material and electrically connected thereto. The control terminal 54b extending vertically is fitted by pressing in another through-hole provided in the conductive layer 31k and electrically connected thereto.

The pin 55a extending vertically is fitted by pressing in the through-hole provided in the conductive layer 31l and electrically connected thereto. The pin 55a has a bottom end bonded to the conductive plate 13 via a bonding material (not illustrated) such as solder or a sintered material and electrically connected thereto. The control terminal 55b extending vertically is fitted by pressing in another through-hole provided in the conductive layer 31l and electrically connected thereto.

The pin 56a extending vertically is fitted by pressing in the through-hole provided in the conductive layer 31m and electrically connected thereto. The pin 56a has a bottom end bonded to one of two semiconductor chips 60 via a bonding material (not illustrated) such as solder or a sintered material and electrically connected thereto. The control terminal 56b extending vertically is fitted by pressing in another through-hole provided in the conductive layer 31m and electrically connected thereto.

The pin 57a extending vertically is fitted by pressing in the through-hole provided in the conductive layer 31n and electrically connected thereto. The pin 57a has a bottom end bonded to the other one of the two semiconductor chips 60 via a bonding material (not illustrated) such as solder or a sintered material and electrically connected thereto. The control terminal 57b extending vertically is fitted by pressing in another through-hole provided in the conductive layer 31n and electrically connected thereto.

The pins 53 extending vertically are fitted by pressing in the through-holes provided in the conductive layer 31o and electrically connected thereto. The pins 53 have bottom ends bonded to the conductive plate 16 via a bonding material (not illustrated) such as solder or a sintered material and electrically connected thereto.

The pins 58 extending vertically are fitted by pressing in the through-holes provided in the conductive layer 31p and electrically connected thereto. The pins 58 have bottom ends bonded to the conductive plate 12 via a bonding material (not illustrated) such as solder or a sintered material and electrically connected thereto.

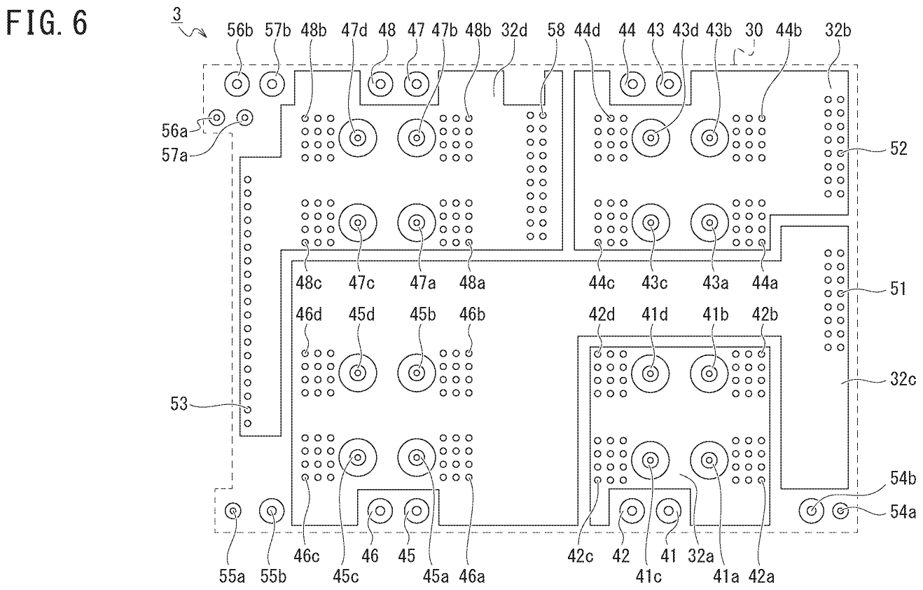

FIG. 6 is a plan view illustrating conductive layers 32a to 32d as the second layer from the top inside the wiring board 3 in an extracted manner. In FIG. 6, the external shape of the insulating layer 30 around the conductive layers 32a to 32d is schematically illustrated by a broken line. The conductive layers 32a to 32d face the conductive layers 31a to 31p illustrated in FIG. 5 via the insulating layer 30, the conductive layers 31a to 31p being above the conductive layers 32a to 32d. The conductive layers 32a to 32d each have through-holes.

The pins 41a to 41d extending vertically pass through the through-holes provided in the conductive layer 32a, with a clearance. The pins 42a to 42d extending vertically are fitted by pressing in other through-holes provided in the conductive layer 32a and electrically connected thereto.

The pins 43a to 43d extending vertically pass through the through-holes provided in the conductive layer 32b, with a clearance. The pins 44a to 44d, 52 extending vertically are fitted by pressing in other through-holes provided in the conductive layer 32b and electrically connected thereto.

The pins 45a to 45d extending vertically pass through the through-holes provided in the conductive layer 32c, with a clearance. The pins 46a to 46d, 51 extending vertically are fitted by pressing in other through-holes provided in the conductive layer 32c and electrically connected thereto.

The pins 47a to 47d extending vertically pass through the through-holes provided in the conductive layer 32d, with a clearance. The pins 48a to 48d, 53, 58 extending vertically are fitted by pressing in other through-holes provided in the conductive layer 32d and electrically connected thereto.

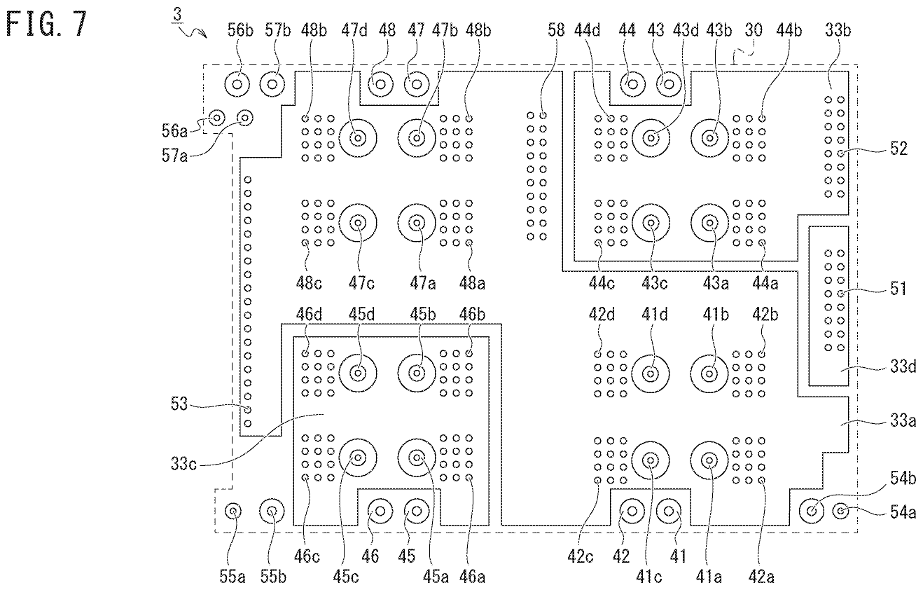

FIG. 7 is a plan view illustrating conductive layers 33a to 33d as the third layer from the top inside the wiring board 3 in an extracted manner. In FIG. 7, the external shape of the insulating layer 30 around the conductive layers 33a to 33d is schematically illustrated by a broken line. The conductive layers 33a to 33d face the conductive layers 32a to 32d illustrated in FIG. 6 via the insulating layer 30, the conductive layers 32a to 32d being above the conductive layers 33a to 33d. The conductive layers 33a to 33d each have through-holes.

The pins 41a to 41d, 47a to 47d extending vertically pass through the through-holes provided in the conductive layer 33a, with a clearance. The pins 42a to 42d, 48a to 48d, 53, 58 extending vertically are fitted by pressing in other through-holes provided in the conductive layer 33a and electrically connected thereto.

The pins 43a to 43d extending vertically pass through the through-holes provided in the conductive layer 33b, with a clearance. The pins 44a to 44d, 52 extending vertically are fitted by pressing in other through-holes provided in the conductive layer 33b and electrically connected thereto.

The pins 45a to 45d extending vertically pass through the through-holes provided in the conductive layer 33c, with a clearance. The pins 46a to 46d extending vertically are fitted by pressing in other through-holes provided in the conductive layer 33c and electrically connected thereto.

The pins 51 extending vertically are fitted by pressing in the through-holes provided in the conductive layer 33d and electrically connected thereto.

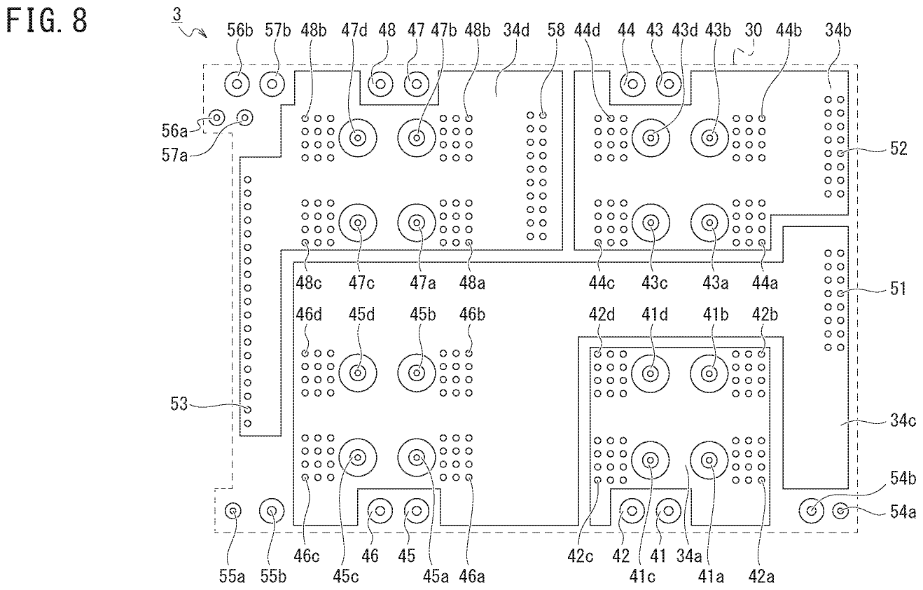

FIG. 8 is a plan view illustrating lowermost conductive layers 34a to 34d as the fourth layer from the top of the wiring board 3 in an extracted manner. In FIG. 8, the external shape of the insulating layer 30 above the conductive layers 34a to 34d is schematically illustrated by a broken line. The conductive layers 34a to 34d face the conductive layers 33a to 33d illustrated in FIG. 7 via the insulating layer 30, the conductive layers 33a to 33d being above the conductive layers 34a to 34d. The conductive layers 34a to 34d have the same plane patterns as the conductive layers 32a to 32d as the second layer from the top of the wiring board 3 as illustrated in FIG. 6. The conductive layer 33a illustrated in FIG. 7 is sandwiched between the conductive layer 32c illustrated in FIG. 6 and the conductive layer 34c illustrated in FIG. 8 via the insulating layer 30. The conductive layers 34a to 34d each have through-holes.

The pins 41a to 41d extending vertically pass through the through-holes provided in the conductive layer 34a, with a clearance. The pins 42a to 42d extending vertically are fitted by pressing in other through-holes provided in the conductive layer 34a and electrically connected thereto.

The pins 43a to 43d extending vertically pass through the through-holes provided in the conductive layer 34b, with a clearance. The pins 44a to 44d, 52 extending vertically are fitted by pressing in other through-holes provided in the conductive layer 34b and electrically connected thereto.

The pins 45a to 45d extending vertically pass through the through-holes provided in the conductive layer 34c, with a clearance. The pins 46a to 46d, 51 extending vertically are fitted by pressing in other through-holes provided in the conductive layer 34c and electrically connected thereto.

The pins 47a to 47d extending vertically pass through the through-holes provided in the conductive layer 34d, with a clearance. The pins 48a to 48d, 53, 58 extending vertically are fitted by pressing in other through-holes provided in the conductive layer 34d and electrically connected thereto.

Note that the wiring board 3 having a four-layer structure including the conductive layers 31a to 31p as the first layer from the top of the wiring board 3, illustrated in FIG. 5, the conductive layers 32a to 32d as the second layer from the top of the wiring board 3, illustrated in FIG. 6, the conductive layers 33a to 33d as the third layer from the top of the wiring board 3, illustrated in FIG. 7, and the conductive layers 34a to 34d as the fourth layer from the top of the wiring board 3, illustrated in FIG. 8, has been described herein. However, the order of the layers is not particularly limited and may be changed. The wiring board 3 may have a three-layer structure that does not include either of the conductive layers 32a to 32d as the second layer from the top of the wiring board 3, illustrated in FIG. 6, and the conductive layers 34a to 34d as the fourth layer from the top of the wiring board 3, illustrated in FIG. 8. Alternatively, the wiring board 3 may have a multilayer structure including five or more layers further including other conductive layers in addition to the four layers.

In FIG. 2 and FIG. 3, a sealing resin 8 sealing the semiconductor chips 61a to 61d, 62a to 62d, 63a to 63d, 64a to 64d and the wiring board 3 is schematically illustrated by a broken line. In FIG. 2 and FIG. 3, the sealing resin 8 has a generally rectangular solid shape, but the shape of the sealing resin 8 is not particularly limited. The sealing resin 8 is made of an insulating resin material such as epoxy-based resin, for example. The sealing resin 8 may be collectively formed by transfer molding or the like. Alternatively, the sealing resin 8 may include a frame as a portion integrally formed with the positive terminal 21, the negative terminal 22, the intermediate terminal 23, the output terminal 24, and the control terminals 41 to 48, 54b, 55b, 56b, 57b by transfer molding (primary molding) or the like, and a portion filled inside the frame by transfer molding (secondary molding) or the like.

In the semiconductor device according to the first embodiment, a current path between the positive terminal 21 and the negative terminal 22, a current path between the positive terminal 21 and the intermediate terminal 23, and a current path between the negative terminal 22 and the intermediate terminal 23 are formed. In order to reduce the inductance in each of the current paths, the following two methods are considered: a path (distance) through which electricity flows is shortened; and the inductance is reduced through the effect of mutual inductance by shortening the distance between the forward and reverse current paths.

Current Path between Positive Terminal 21 and Negative Terminal 22

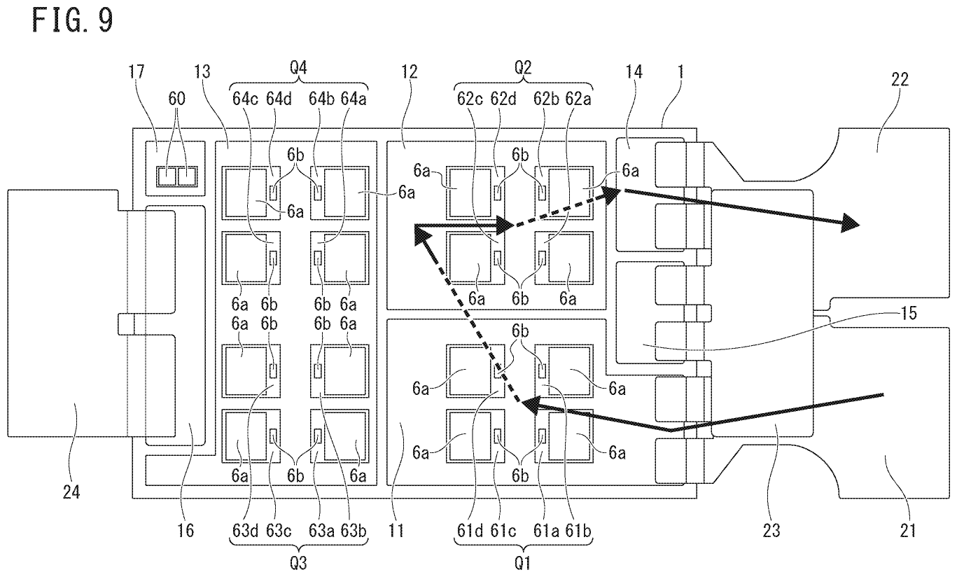

Here, with reference to FIG. 9 to FIG. 11, the current path between the positive terminal 21 and the negative terminal 22 in the semiconductor device according to the first embodiment will be described. FIG. 9 illustrates a planar layout of the semiconductor device according to the first embodiment without the wiring board 3. In the current path between the positive terminal 21 and the negative terminal 22, solid-line arrows in FIG. 9 indicate current paths passing through the semiconductor chips 61a to 61d, 62a to 62d and the conductive plates 11, 12, 14, and broken-line arrows indicate current paths passing through the wiring board 3 omitted in FIG. 9.

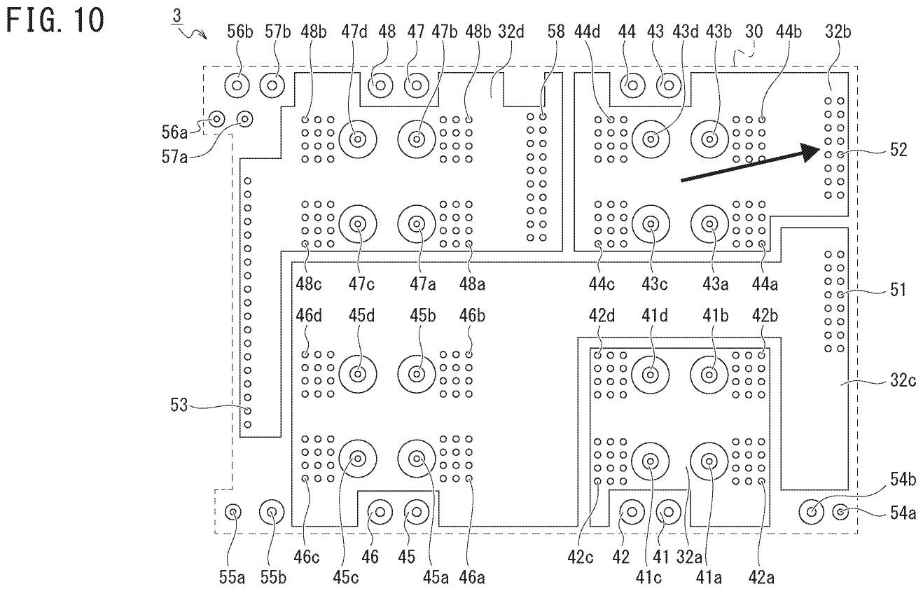

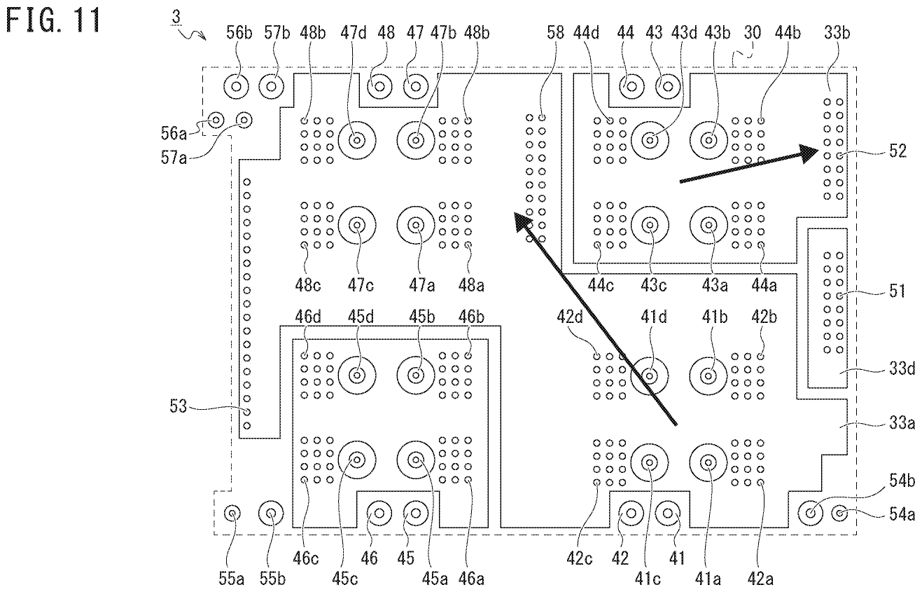

FIG. 10 illustrates the conductive layers 32a to 32d as the second layer from the top of the wiring board 3. A solid-line arrow in FIG. 10 indicates a current path passing through the conductive layer 32b, in the current path between the positive terminal 21 and the negative terminal 22. FIG. 11 illustrates the conductive layers 33a to 33d as the third layer from the top of the wiring board 3. Solid-line arrows in FIG. 11 indicate current paths passing through the conductive layer 33a, 33b, in the current path between the positive terminal 21 and the negative terminal 22.

The current path from the positive terminal 21 to the negative terminal 22 starts from the positive terminal 21 illustrated in FIG. 9 and reaches the negative terminal 22 via the conductive plate 11, the semiconductor chips 61a to 61d from the drain electrodes on the bottom surface sides thereof to the source electrodes 6a on the top surface sides thereof, the pins 42a to 42d, the conductive layer 33a, and the pins 58 illustrated in FIG. 11, the conductive plate 12 and the semiconductor chips 62a to 62d from the drain electrodes on the bottom surface sides thereof to the source electrodes 6a on the top surface sides thereof, illustrated in FIG. 9, the pins 44a to 44d, the conductive layers 32b, 33b, and the pins 52 illustrated in FIG. 10 and FIG. 11, and the conductive plate 14 illustrated in FIG. 9. Note that the conductive layers 34a to 34d as the fourth layer from the top of the wiring board 3, illustrated in FIG. 8, have the same plane pattern as the conductive layers 32a to 32d as the second layer from the top of the wiring board 3, illustrated in FIG. 10, and have the same current path as the conductive layers 32a to 32d.

In the semiconductor device according to the first embodiment, the semiconductor chips 61a to 61d of the upper arm Q1 and the semiconductor chips 62a to 62d of the lower arm Q2 are disposed on the side where the positive terminal 21 and the negative terminal 22 are provided, so that the current path between the positive terminal 21 and the negative terminal 22 is shortened, thereby making it possible to reduce the inductance.

Current Path between Positive Terminal 21 and Intermediate Terminal 23

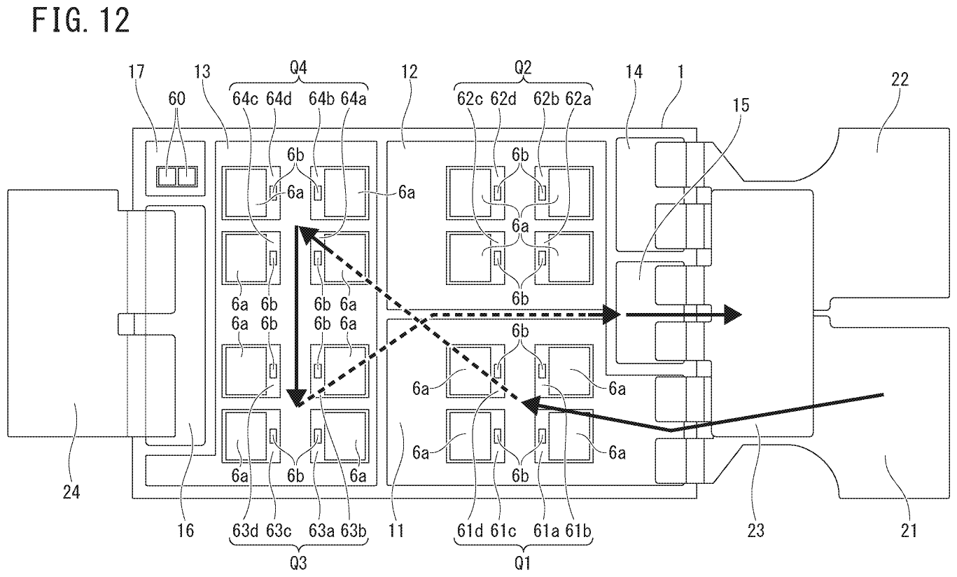

Next will be described the current path between the positive terminal 21 and the intermediate terminal 23 in the semiconductor device according to the first embodiment, with reference to FIG. 12 to FIG. 14. FIG. 12 illustrates a planar layout of the semiconductor device according to the first embodiment without the wiring board 3. In the current path between the positive terminal 21 and the intermediate terminal 23, solid-line arrows in FIG. 12 indicate current paths passing through the semiconductor chips 61a to 61d, 63a to 63d, 64a to 64d, and the conductive plates 11, 13, 15, and broken-line arrows indicate current paths passing through the wiring board 3 omitted in FIG. 12.

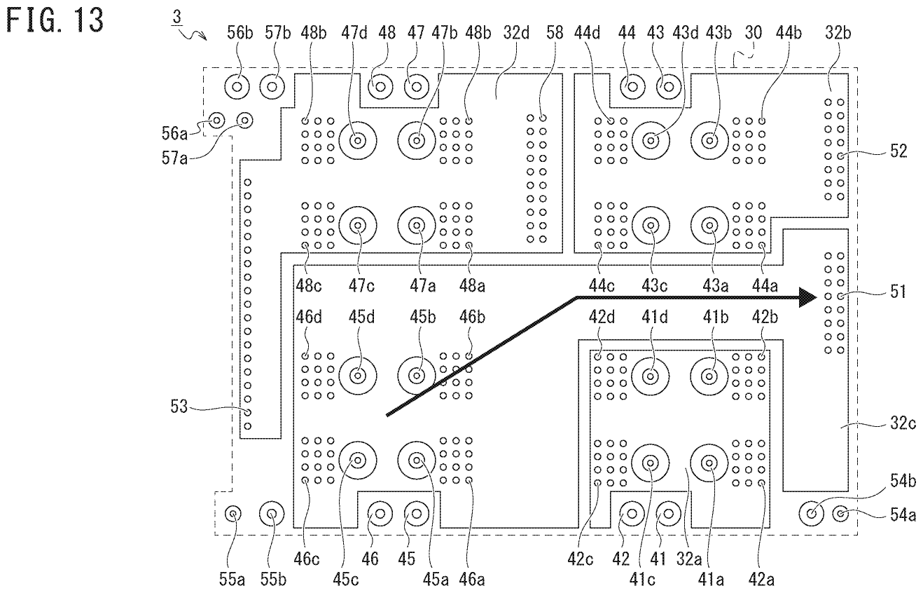

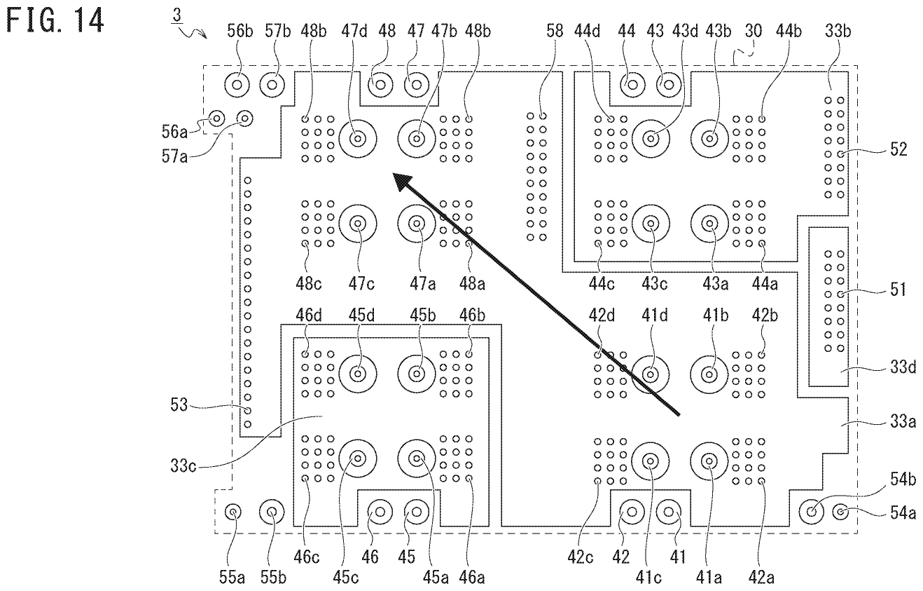

FIG. 13 illustrates the conductive layers 32a to 32d as the second layer from the top of the wiring board 3. A solid-line arrow in FIG. 13 indicates a current path passing through the conductive layer 32c, in the current path between the positive terminal 21 and the intermediate terminal 23. FIG. 14 illustrates the conductive layers 33a to 33d as the third layer from the top of the wiring board 3. A solid-line arrow in FIG. 14 indicates a current path passing through the conductive layer 33a, in the current path between the positive terminal 21 and the intermediate terminal 23.

The current path from the positive terminal 21 to the intermediate terminal 23 starts from the positive terminal 21 illustrated in FIG. 12 and reaches the intermediate terminal 23 via the conductive plate 11, the semiconductor chips 61a to 61d from the drain electrodes on the bottom surface sides thereof to the source electrodes 6a on the top surface sides thereof, the pins 42a to 42d, the conductive layer 33a, and the pins 48a to 48d illustrated in FIG. 14, the semiconductor chips 64a to 64d from the source electrodes 6a on the top surface sides thereof to the drain electrodes on the bottom surface sides thereof, the conductive plate 13, and the semiconductor chips 63a to 63d from the drain electrodes on the bottom surface sides thereof to the source electrodes 6a on the top surface sides thereof, illustrated in FIG. 12, the pins 46a to 46d, the conductive layer 32c, and the pins 51 illustrated in FIG. 13, and the conductive plate 15 illustrated in FIG. 12. Note that the conductive layers 34a to 34d as the fourth layer from the top of the wiring board 3, illustrated in FIG. 8, have the same plane pattern as the conductive layers 32a to 32d as the second layer from the top of the wiring board 3, illustrated in FIG. 13, and have the same current path as the conductive layers 32a to 32d.

In the current path from the positive terminal 21 to the intermediate terminal 23, the conductive layer 32c illustrated in FIG. 13 is disposed close to the conductive layer 33a (illustrated in FIG. 14) located below the conductive layer 32c in the thickness direction of the wiring board 3 via the insulating layer 30, and current flows in the opposite direction, so that the effect of mutual inductance is achieved. Besides, the conductive layer 34c illustrated in FIG. 8 is disposed close to the conductive layer 33a (illustrated in FIG. 14) located above the conductive layer 34c in the thickness direction of the wiring board 3 via the insulating layer 30, and current flows in the opposite direction, so that the effect of mutual inductance is achieved.

Current Path between Negative Terminal 22 and Intermediate Terminal 23

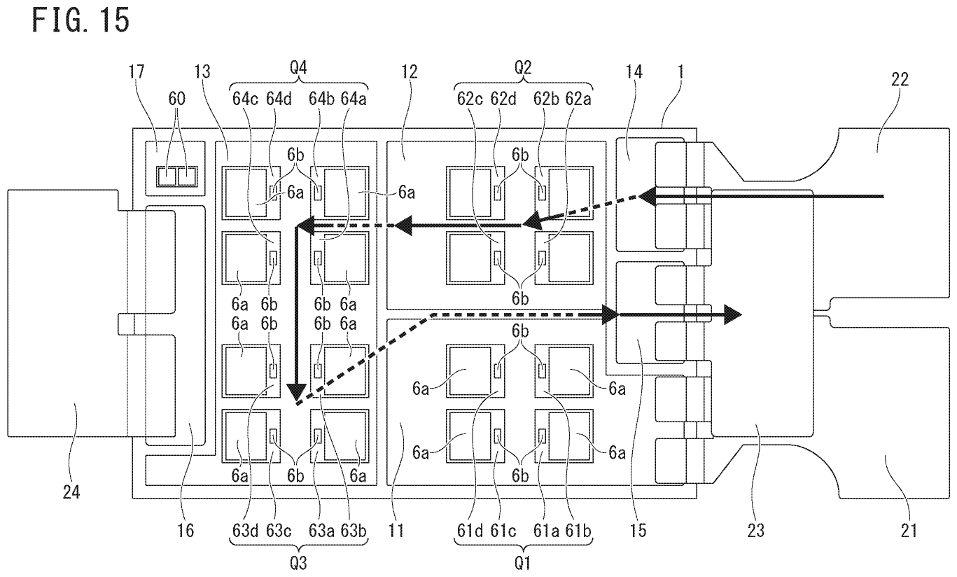

Next will be described the current path between the negative terminal 22 and the intermediate terminal 23 in the semiconductor device according to the first embodiment, with reference to FIG. 15 to FIG. 17. FIG. 15 illustrates a planar layout of the semiconductor device according to the first embodiment without the wiring board 3. In the current path between the negative terminal 22 and the intermediate terminal 23, solid-line arrows in FIG. 15 indicate current paths passing through the semiconductor chips 62a to 62d, 63a to 63d, 64a to 64d and the conductive plates 12 to 15, and broken-line arrows indicate current paths passing through the wiring board 3 omitted in FIG. 15.

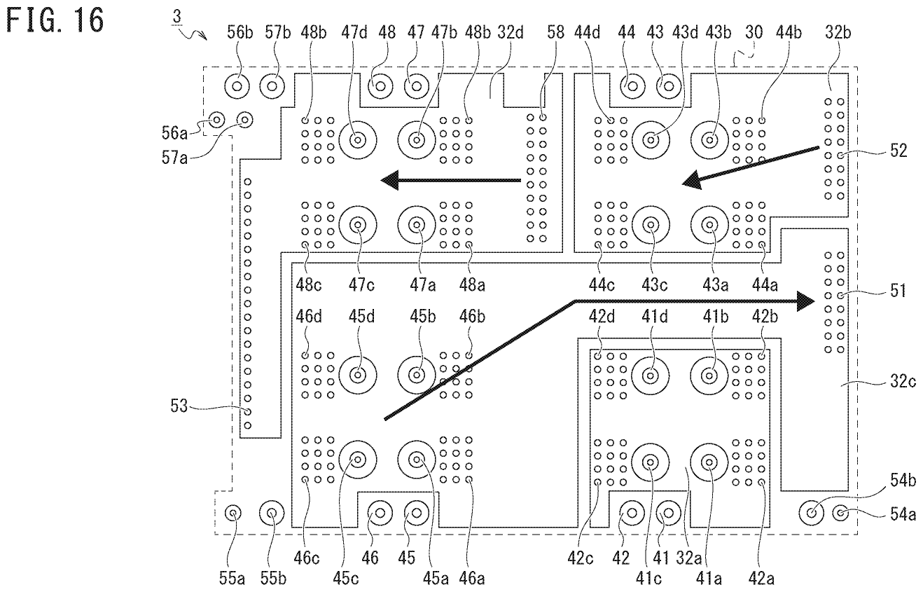

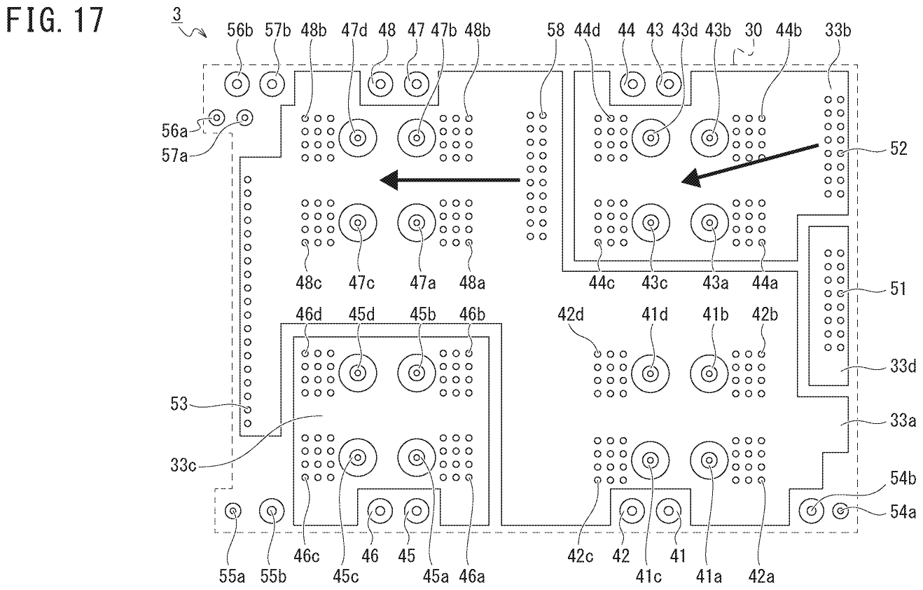

FIG. 16 illustrates the conductive layers 32a to 32d as the second layer from the top of the wiring board 3. Solid-line arrows in FIG. 16 indicate current paths passing through the conductive layers 32b to 32d, in the current path between the negative terminal 22 and the intermediate terminal 23. FIG. 17 illustrates the conductive layers 33a to 33d as the third layer from the top of the wiring board 3. Solid-line arrows in FIG. 17 indicate current paths passing through the conductive layers 33a, 33b, in the current path between the negative terminal 22 and the intermediate terminal 23.

The current path from the negative terminal 22 to the intermediate terminal 23 starts from the negative terminal 22 illustrated in FIG. 15 and reaches the intermediate terminal 23 via the conductive plate 14, the pins 52, the conductive layers 32b, 33b, and the pins 44a to 44d illustrated in FIG. 16 and FIG. 17, the semiconductor chips 62a to 62d from the source electrodes 6a on the top surface sides thereof to the drain electrodes on the bottom surface sides thereof and the conductive plate 12, illustrated in FIG. 15, the pins 58, the conductive layers 32d, 33a, and the pins 48a to 48d illustrated in FIG. 16 and FIG. 17, the semiconductor chips 64a to 64d from the source electrodes 6a on the top surface sides thereof to the drain electrodes on the bottom surface sides thereof, the conductive plate 13, and the semiconductor chips 63a to 63d from the drain electrodes on the bottom surface sides thereof to the source electrodes 6a on the top surface sides thereof, illustrated in FIG. 15, the pins 46a to 46d, the conductive layer 32c, and the pins 51 illustrated in FIG. 16, and the conductive plate 15 illustrated in FIG. 15. Note that the conductive layers 34a to 34d as the fourth layer from the top of the wiring board 3, illustrated in FIG. 8, have the same plane pattern as the conductive layers 32a to 32d as the second layer from the top of the wiring board 3, illustrated in FIG. 16, and have the same current path as the conductive layers 32a to 32d.

In the current path from the negative terminal 22 to the intermediate terminal 23, the conductive layers 32b, 32d illustrated in FIG. 16 are disposed horizontally close to the conductive layer 32c in the same layer, and current flows in the opposite direction, so that the effect of mutual inductance is achieved. Besides, the conductive layers 34b, 34d illustrated in FIG. 8 are disposed horizontally close to the conductive layer 34c in the same layer, and current flows in the opposite direction, so that the effect of mutual inductance is achieved.

### Comparative Example

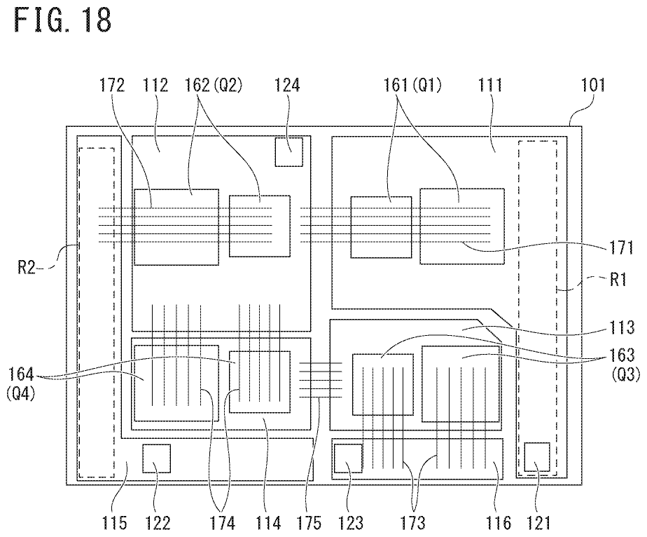

Next will be described a semiconductor device according to a comparative example. The equivalent circuit of the semiconductor device according to the comparative example is similar to the three-level circuit illustrated in FIG. 1. As illustrated in FIG. 18, the semiconductor device according to the comparative example includes an insulating substrate 101, conductive plates 111 to 116 provided on the insulating substrate 101, and semiconductor chips 161 to 164, a positive terminal 121, a negative terminal 122, an intermediate terminal 123, and an output terminal 124 disposed on the conductive plates 111 to 116.

The positive terminal 121, the negative terminal 122, the intermediate terminal 123, and the output terminal 124 of the semiconductor device according to the comparative example are arranged in the same manner as the semiconductor device according to the first embodiment. The positive terminal 121, the negative terminal 122, and the intermediate terminal 123 are provided on the same side. The positive terminal 121 is provided on the conductive plate 111. The negative terminal 122 is provided on the conductive plate 115. The intermediate terminal 123 is provided on the conductive plate 116. The output terminal 124 is provided on the opposite side to the positive terminal 121, the negative terminal 122, and the intermediate terminal 123 across the semiconductor chips 161 to 164. The output terminal 124 is provided on the conductive plate 112.

The semiconductor device according to the comparative example is different from the semiconductor device according to the first embodiment in the arrangement of the semiconductor chips 161 to 164. The semiconductor chip 161 corresponds to the upper arm Q1 illustrated in FIG. 1. The semiconductor chip 161 is provided on the conductive plate 111. The top surface side of the semiconductor chip 161 is electrically connected to the conductive plate 112 via a wire (bonding wire) 171.

The semiconductor chip 162 corresponds to the lower arm Q2 illustrated in FIG. 1. The semiconductor chip 162 is provided on the conductive plate 112. The top surface side of the semiconductor chip 162 is electrically connected to the conductive plate 115 via a bonding wire 172.

The semiconductor chip 163 corresponds to the intermediate arm Q3 illustrated in FIG. 1. The semiconductor chip 163 is provided on the conductive plate 113. The conductive plate 113 is electrically connected to the conductive plate 114 via a bonding wire 175. The top surface side of the semiconductor chip 163 is electrically connected to the conductive plate 116 via a bonding wire 173.

The semiconductor chip 164 corresponds to the intermediate arm Q4 illustrated in FIG. 1. The semiconductor chip 164 is provided on the conductive plate 114. The top surface side of the semiconductor chip 164 is electrically connected to the conductive plate 112 via a bonding wire 174.

In the semiconductor device according to the comparative example, due to the positional restrictions of the positive terminal 121, the negative terminal 122, the intermediate terminal 123, and the output terminal 124, and the arrangement restrictions of the conductive plates 111 to 116, the semiconductor chip 161 of the upper arm Q1 and the semiconductor chip 162 of the lower arm Q2 are provided on the side where the output terminal 124 is provided. The semiconductor chips 163, 164 of the intermediate arms Q3, Q4 are provided on the side where the positive terminal 121, the negative terminal 122, and the intermediate terminal 123 are provided.

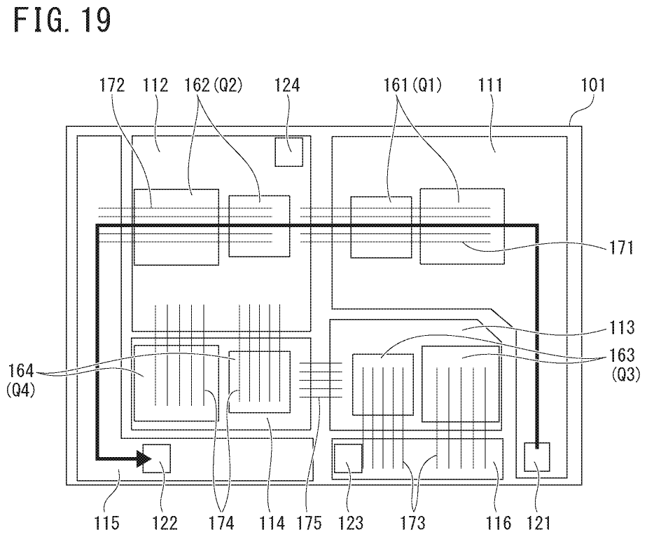

In FIG. 19, a current path from the positive terminal 121 to the negative terminal 122 in the semiconductor device according to the comparative example is indicated by an arrow. Current flows from the positive terminal 121 to the negative terminal 122 via the conductive plate 111, the semiconductor chip 161, the bonding wire 171, the conductive plate 112, the semiconductor chip 162, the bonding wire 172, and the conductive plate 115.

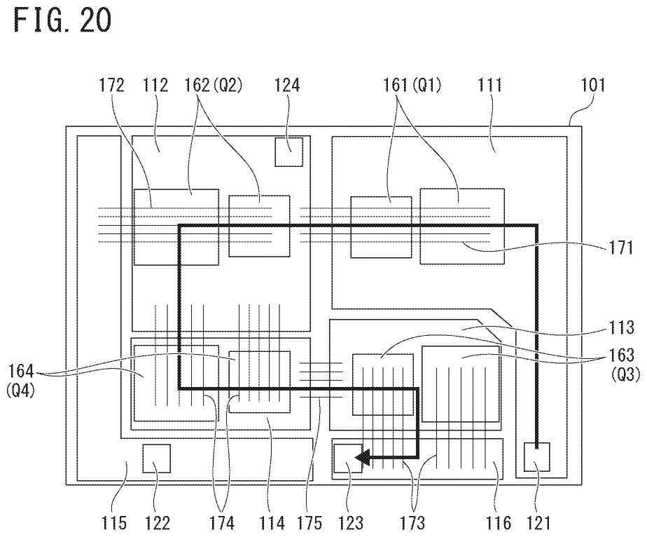

In FIG. 20, a current path from the positive terminal 121 to the intermediate terminal 123 in the semiconductor device according to the comparative example is indicated by an arrow. Current flows from the positive terminal 121 to the intermediate terminal 123 via the conductive plate 111, the semiconductor chip 161, the bonding wire 171, the conductive plate 112, the bonding wire 174, the semiconductor chip 164, the conductive plate 114, the bonding wire 175, the conductive plate 113, the semiconductor chip 163, the bonding wire 173, and the conductive plate 116.

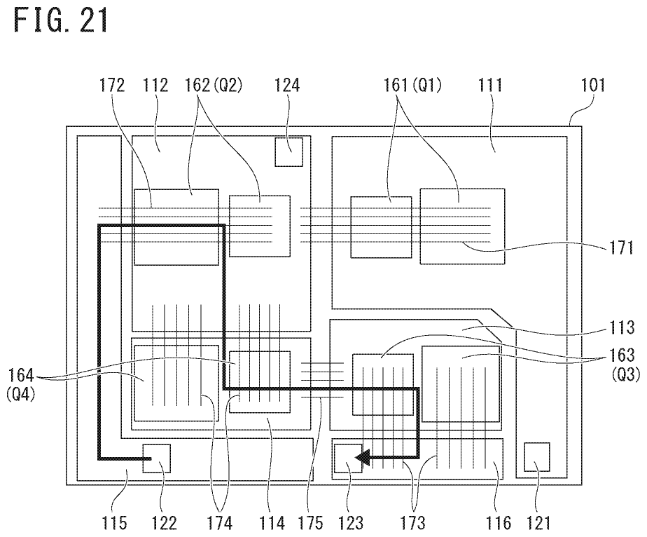

In FIG. 21, a current path from the negative terminal 122 to the intermediate terminal 123 in the semiconductor device according to the comparative example is indicated by an arrow. Current flows from the negative terminal 122 to the intermediate terminal 123 via the conductive plate 115, the bonding wire 172, the semiconductor chip 162, the conductive plate 112, the bonding wire 174, the semiconductor chip 164, the conductive plate 114, the bonding wire 175, the conductive plate 113, the semiconductor chip 163, the bonding wire 173, and the conductive plate 116.

In the semiconductor device according to the comparative example, the semiconductor chip 161 of the upper arm Q1 and the semiconductor chip 162 of the lower arm Q2 are provided on the side where the output terminal 124 is provided. As a result, the current path from the positive terminal 121 to the negative terminal 122, illustrated in FIG. 19, is long, which increases an inductance value. In contrast, in the case of the semiconductor device according to the first embodiment, since the semiconductor chips 61a to 61d of the upper arm Q1 and the semiconductor chips 62a to 62d of the lower arm Q2 are provided on the side where the positive terminal 21, the negative terminal 22, and the intermediate terminal 23 are provided, thereby making it possible to shorten the current path and to reduce the inductance between the positive terminal 21 and the negative terminal 22.

Besides, in the semiconductor device according to the comparative example, since wiring is routed in the planar direction with the use of the conductive plates 111 to 115 and the bonding wires 171 to 175, the wire length is long, which increases the inductance between the positive terminal 121 and the intermediate terminal 123, illustrated in FIG. 20 and FIG. 21, and the inductance between the intermediate terminal 123 and the negative terminal 122. In contrast, in the case of the semiconductor device according to the first embodiment, due to the three-dimensional wiring layout using the wiring board 3, the effect of mutual inductance is achieved. This makes it possible to reduce the inductance between the positive terminal 21 and the intermediate terminal 23 and the inductance between the intermediate terminal 23 and the negative terminal 22.

In the semiconductor device according to the comparative example, wiring is routed in the planar direction with the use of the conductive plates 111 to 115 and the bonding wires 171 to 175, and wiring regions R1, R2 schematically indicated by a broken line in FIG. 18 are required, which increases a module size. In contrast, in the case of the semiconductor device according to the first embodiment, due to the three-dimensional wiring using the wiring board 3, the module can be reduced in size.

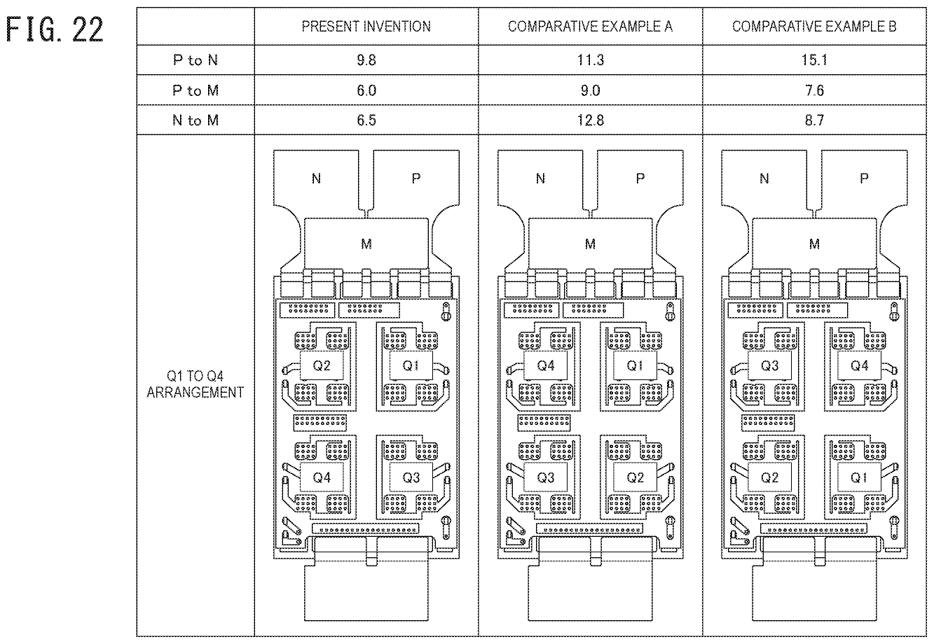

FIG. 22 exhibits simulation results of an inductance value (described as “P to N” in FIG. 22 with a unit [nH]) between the positive terminal and the negative terminal, an inductance value (described as “P to M” in FIG. 22 with a unit [nH]) between the positive terminal and the intermediate terminal, and an inductance value (described as “N to M” in FIG. 22 with a unit [nH]) between the negative terminal and the intermediate terminal, in terms of Example of the semiconductor device according to the first embodiment (described as “PRESENT INVENTION” in FIG. 22) and Comparative Examples A, B.

As illustrated in the fields of “Q1 to Q4 ARRANGEMENT” in FIG. 22, Example of the semiconductor device according to the first embodiment exhibits a configuration in which the semiconductor chips corresponding to the upper arm Q1 and the lower arm Q2 illustrated in FIG. 1 are disposed on the side where the positive terminal, the negative terminal, and the intermediate terminal are provided, and the semiconductor chips corresponding to the intermediate arm Q3 and the intermediate arm Q4 illustrated in FIG. 1 are disposed on the side where the output terminal is provided. Comparative Example A exhibits a configuration in which the semiconductor chips corresponding to the upper arm Q1 and the intermediate arm Q4 illustrated in FIG. 1 are disposed on the side where the positive terminal, the negative terminal, and the intermediate terminal are provided, and the semiconductor chips corresponding to the lower arm Q2 and the intermediate arm Q3 illustrated in FIG. 1 are disposed on the side where the output terminal is provided. Comparative Example B exhibits a configuration in which the semiconductor chips corresponding to the intermediate arm Q3 and the intermediate arm Q4 illustrated in FIG. 1 are disposed on the side where the positive terminal, the negative terminal, and the intermediate terminal are provided, and the semiconductor chips corresponding to the upper arm Q1 and the lower arm Q2 illustrated in FIG. 1 are disposed on the side where the output terminal is provided.

As illustrated in FIG. 22, since the semiconductor chips corresponding to the upper arm Q1 and the lower arm Q2 are disposed on the side where the positive terminal and the negative terminal are provided in Example, the inductance value between the positive terminal and the negative terminal in Example can be reduced more than in Comparative Examples A, B. The inductance value between the positive terminal and the intermediate terminal and the inductance value between the negative terminal and the intermediate terminal in Example can be reduced more than in Comparative Examples A, B, due to the effect of mutual inductance resulting from the use of the wiring board 3.

### Second Embodiment

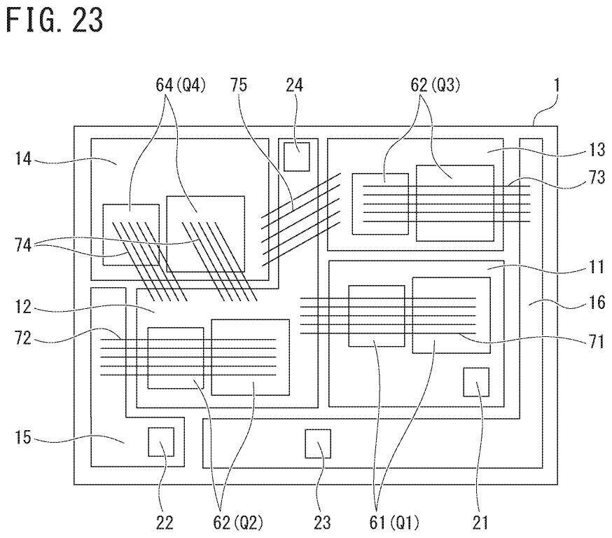

FIG. 23 is a plan view of a semiconductor device according to a second embodiment. As illustrated in FIG. 23, the semiconductor device according to the second embodiment is different from the semiconductor device according to the first embodiment in that no wiring board 3 is provided, and bonding wires 71 to 75 are used for electrical connection. The semiconductor device according to the second embodiment includes the conductive plates 11 to 16 provided on the top surface side of the insulating substrate 1, and the positive terminal 21, the negative terminal 22, the intermediate terminal 23, the output terminal 24, and semiconductor chips 61 to 64 provided on the top surface sides of the conductive plates 11 to 16.

The positive terminal 21, the negative terminal 22, the intermediate terminal 23, and the output terminal 24 are arranged in the same manner as the semiconductor device according to the first embodiment. The positive terminal 21, the negative terminal 22, and the intermediate terminal 23 are provided on the same side. The positive terminal 21 is provided on the conductive plate 11. The negative terminal 22 is provided on the conductive plate 15. The intermediate terminal 23 is provided on the conductive plate 16. The output terminal 24 is provided on the opposite side to the positive terminal 21, the negative terminal 22, and the intermediate terminal 23 across the semiconductor chips 61 to 64. The output terminal 24 is provided on the conductive plate 12.

The semiconductor chip 61 corresponds to the upper arm Q1 illustrated in FIG. 1. The semiconductor chip 62 corresponds to the lower arm Q2 illustrated in FIG. 1. The semiconductor chip 63 corresponds to the intermediate arm Q3 illustrated in FIG. 1. The semiconductor chip 64 corresponds to the intermediate arm Q4 illustrated in FIG. 1. The semiconductor chips 61 to 64 are each constituted by the combination of an IGBT chip and a diode chip, for example. The IGBT chip includes a first main electrode (an emitter electrodes) and a gate electrode on its top surface side, and a second main electrode (a collector electrode) on its bottom surface side. The diode chip includes an anode electrode on its top surface side, and a cathode electrode on its bottom surface side.

The collector electrode and the cathode electrode on the bottom surface side of the semiconductor chip 61 are electrically connected to the conductive plate 11. The emitter electrode and the anode electrode on the top surface side of the semiconductor chip 61 are electrically connected to the conductive plate 12 via the bonding wire 71.

The collector electrode and the cathode electrode on the bottom surface side of the semiconductor chip 62 are electrically connected to the conductive plate 12. The emitter electrode and the anode electrode on the top surface side of the semiconductor chip 62 are electrically connected to the conductive plate 15 via the bonding wire 72.

The collector electrode and the cathode electrode on the bottom surface side of the semiconductor chip 63 are electrically connected to the conductive plate 13. The conductive plate 13 is electrically connected to the conductive plate 14 via the bonding wire 75. The emitter electrode and the anode electrode on the top surface side of the semiconductor chip 63 are electrically connected to the conductive plate 16 via the bonding wire 73.

The collector electrode and the cathode electrode on the bottom surface side of the semiconductor chip 64 are electrically connected to the conductive plate 14. The emitter electrode and the anode electrode on the top surface side of the semiconductor chip 64 are electrically connected to the conductive plate 12 via the bonding wire 74.

In the semiconductor device according to the second embodiment, the current path from the positive terminal 21 to the negative terminal 22 starts from the positive terminal 21 and reaches the negative terminal 22 via the conductive plate 11, the semiconductor chip 61, the bonding wire 71, the conductive plate 12, the semiconductor chip 62, the bonding wire 72, and the conductive plate 15.

In the semiconductor device according to the second embodiment, the current path from the positive terminal 21 to the intermediate terminal 23 starts from the positive terminal 21 and reaches the intermediate terminal 23 via the conductive plate 11, the semiconductor chip 61, the bonding wire 71, the conductive plate 12, the bonding wire 74, the semiconductor chip 64, the conductive plate 14, the bonding wire 75, the conductive plate 13, the semiconductor chip 63, the bonding wire 73, and the conductive plate 16.

In the semiconductor device according to the second embodiment, the current path from the negative terminal 22 to the intermediate terminal 23 starts from the negative terminal 22 and reaches the intermediate terminal 23 via the conductive plate 15, the bonding wire 72, the semiconductor chip 62, the conductive plate 12, the bonding wire 74, the semiconductor chip 64, the conductive plate 14, the bonding wire 75, the conductive plate 13, the semiconductor chip 63, the bonding wire 73, and the conductive plate 16.

The other configuration of the semiconductor device according to the second embodiment is substantially the same as that of the semiconductor device according to the first embodiment, and descriptions thereof are omitted.

In the semiconductor device according to the second embodiment, the semiconductor chip 61 of the upper arm Q1 and the semiconductor chip 62 of the lower arm Q2 are provided on the side where the positive terminal 21, the negative terminal 22, and the intermediate terminal 23 are provided, thereby making it possible to shorten the current path and to reduce the inductance between the positive terminal 21 and the negative terminal 22.

### Third Embodiment

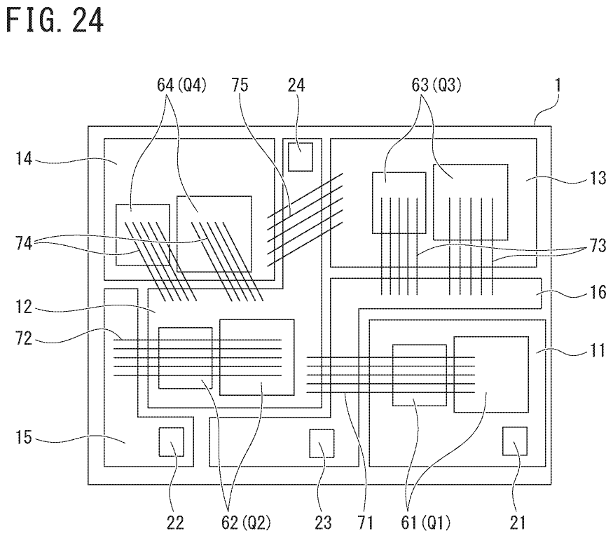

FIG. 24 is a plan view of a semiconductor device according to a third embodiment. As illustrated in FIG. 24, the semiconductor device according to the third embodiment is different from the semiconductor device according to the first embodiment but is the same as the semiconductor device according to the second embodiment in that no wiring board 3 is provided, and the bonding wires 71 to 75 are used for electrical connection.

The semiconductor device according to the third embodiment is different from the semiconductor device according to the second embodiment in that the conductive plate 16 electrically connected to the intermediate terminal 23 is formed not in an L-shaped planar pattern along the outer peripheral surface of the insulating substrate 1, but in a Z-shaped planar pattern to be disposed between the conductive plates 11, 13.

The other configuration of the semiconductor device according to the third embodiment is substantially the same as that of the semiconductor device according to the second embodiment, and descriptions thereof are omitted.

In the semiconductor device according to the third embodiment, the semiconductor chip 61 of the upper arm Q1 and the semiconductor chip 62 of the lower arm Q2 are provided on the side where the positive terminal 21, the negative terminal 22, and the intermediate terminal 23 are provided, thereby making it possible to shorten the current path and to reduce the inductance between the positive terminal 21 and the negative terminal 22.

### Fourth Embodiment

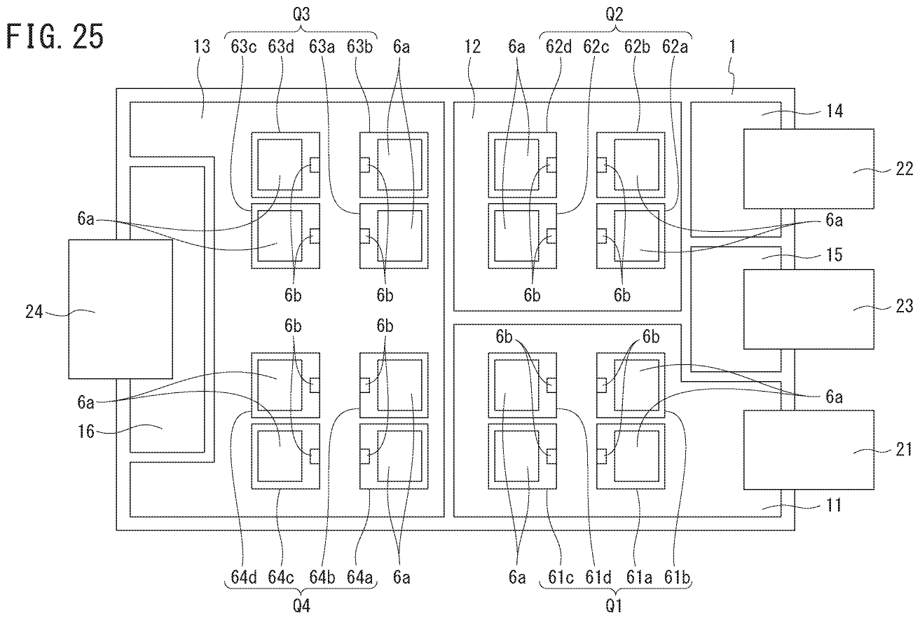

The equivalent circuit of a semiconductor device according to a fourth embodiment is similar to the three-level circuit illustrated in FIG. 1. FIG. 25 is a plan view of the semiconductor device according to the fourth embodiment. As illustrated in FIG. 25, the semiconductor device according to the fourth embodiment includes the insulating substrate 1, the conductive plates 11 to 16 provided on the top surface side of the insulating substrate 1, and the semiconductor chips 61a to 61d, 62a to 62d, 63a to 63d, 64a to 64d, the positive terminal 21, the negative terminal 22, the intermediate terminal 23, and the output terminal 24 provided on the top surface sides of the conductive plates 11 to 16.

The positive terminal 21, the negative terminal 22, the intermediate terminal 23, and the output terminal 24 are arranged in the same manner as the semiconductor device according to the first embodiment. The positive terminal 21, the negative terminal 22, and the intermediate terminal 23 are provided on the same side, and the output terminal 24 is provided on the opposite side to the positive terminal 21, the negative terminal 22, and the intermediate terminal 23 across the semiconductor chips 61a to 61d, 62a to 62d, 63a to 63d, 64a to 64d.

The semiconductor chips 61a to 61d are provided on the top surface side of the conductive plate 11 via a bonding material (not illustrated) such as solder or a sintered material and bonded thereto. The semiconductor chips 61a to 61d correspond to the upper arm Q1 illustrated in FIG. 1. The semiconductor chips 62a to 62d are provided on the top surface side of the conductive plate 12 via a bonding material (not illustrated) such as solder or a sintered material and bonded thereto. The semiconductor chips 62a to 62d correspond to the lower arm Q2 illustrated in FIG. 1. The semiconductor chips 63a to 63d, 64a to 64d are provided on the top surface side of the conductive plate 13 via a bonding material (not illustrated) such as solder or a sintered material and bonded thereto. The semiconductor chips 63a to 63d correspond to the intermediate arm Q3 illustrated in FIG. 1. The semiconductor chips 64a to 64d correspond to the intermediate arm Q4 illustrated in FIG. 1. The semiconductor chips 61a to 61d, 62a to 62d, 63a to 63d, 64a to 64d have the same configuration as in the semiconductor device according to the first embodiment.

The semiconductor device according to the fourth embodiment is the same as the semiconductor device according to the first embodiment in that the semiconductor chips 61a to 61d of the upper arm Q1 and the semiconductor chips 62a to 62d of the lower arm Q2 are provided on the side where the positive terminal 21, the negative terminal 22, and the intermediate terminal 23 are provided, and the semiconductor chips 63a to 63d, 64a to 64d of the intermediate arms Q3, Q4 are provided on the side where the output terminal 24 is provided. However, the semiconductor device according to the fourth embodiment is different from the semiconductor device according to the first embodiment in that the semiconductor chips 63a to 63d, 64a to 64d provided on the side where the output terminal 24 is provided are arranged in a reverse manner. The semiconductor chips 61a to 61d, 62a to 62d, 63a to 63d, 64a to 64d are provided in a matrix form. The semiconductor chips 61a to 61d are provided at positions diagonal to the semiconductor chips 63a to 63d. The semiconductor chips 62a to 62d are provided at positions diagonal to the semiconductor chips 64a to 64d.

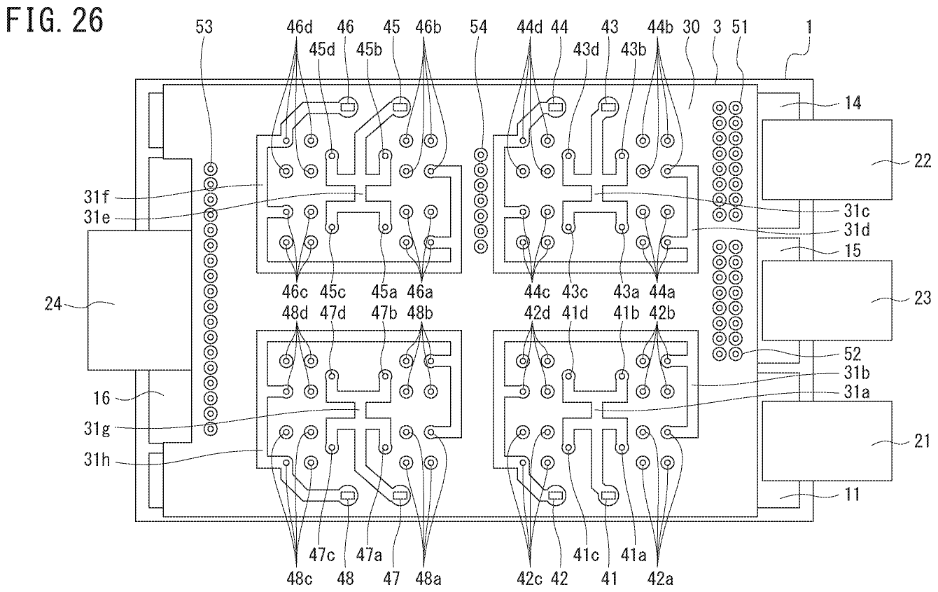

In FIG. 25, a wiring board provided above the semiconductor chips 61a to 61d, 62a to 62d, 63a to 63d, 64a to 64d is not illustrated. FIG. 26 is a plan view illustrating the wiring board 3 provided above the semiconductor chips 61a to 61d, 62a to 62d, 63a to 63d, 64a to 64d of the semiconductor device according to the fourth embodiment. The wiring board 3 includes the insulating layer 30, and the conductive layers 31a to 31h on the top surface side of the insulating layer 30.

The control terminals 41 to 48 are provided to project from the top surface side of the wiring board 3. The control terminal 41 corresponds to the gate terminal G1 of the transistor of the upper arm Q1 illustrated in FIG. 1. The control terminal 42 corresponds to the auxiliary source terminal S1 of the transistor of the upper arm Q1 illustrated in FIG. 1. The control terminal 43 corresponds to the gate terminal G2 of the transistor of the lower arm Q2 illustrated in FIG. 1. The control terminal 44 corresponds to the auxiliary source terminal S2 of the transistor of the lower arm Q2 illustrated in FIG. 1. The control terminal 45 corresponds to the gate terminal G3 of the transistor of the intermediate arm Q3 illustrated in FIG. 1. The control terminal 46 corresponds to the auxiliary source terminal S3 of the transistor of the intermediate arm Q3 illustrated in FIG. 1. The control terminal 47 corresponds to the gate terminal G4 of the transistor of the intermediate arm Q4 illustrated in FIG. 1. The control terminal 48 corresponds to the auxiliary source terminal S4 of the transistor of the intermediate arm Q4 illustrated in FIG. 1.

The conductive layers 31a to 31h have through-holes. The pins 41a to 41d extending vertically are fitted by pressing in the through-holes provided in the conductive layer 31a and electrically connected thereto. The pins 41a to 41d have bottom ends bonded to corresponding gate electrodes 6b of the semiconductor chips 61a to 61d via a bonding material (not illustrated) such as solder or a sintered material and electrically connected thereto. The control terminal 41 extending vertically is fitted by pressing in another through-hole provided in the conductive layer 31a and electrically connected thereto.

The conductive layer 31b has a U-shaped plane pattern to surround the conductive layer 31a. The pins 42a to 42d extending vertically are fitted by pressing in the through-holes provided in the conductive layer 31b and electrically connected thereto. The pins 42a to 42d have bottom ends bonded to corresponding source electrodes 6a of the semiconductor chips 61a to 61d via a bonding material (not illustrated) such as solder or a sintered material and electrically connected thereto. The control terminal 42 extending vertically is fitted by pressing in another through-hole provided in the conductive layer 31b and electrically connected thereto.

The pins 43a to 43d extending vertically are fitted by pressing in the through-holes provided in the conductive layer 31c and electrically connected thereto. The pins 43a to 43d have bottom ends bonded to corresponding gate electrodes 6b of the semiconductor chips 62a to 62d via a bonding material (not illustrated) such as solder or a sintered material and electrically connected thereto. The control terminal 43 extending vertically is fitted by pressing in another through-hole provided in the conductive layer 31c and electrically connected thereto.

The conductive layer 31d has a U-shaped plane pattern to surround the conductive layer 31c. The pins 44a to 44d extending vertically are fitted by pressing in the through-holes provided in the conductive layer 31d and electrically connected thereto. The pins 44a to 44d have bottom ends bonded to corresponding source electrodes 6a of the semiconductor chips 62a to 62d via a bonding material (not illustrated) such as solder or a sintered material and electrically connected thereto. The control terminal 44 extending vertically is fitted by pressing in another through-hole provided in the conductive layer 31d and electrically connected thereto.

The pins 45a to 45d extending vertically are fitted by pressing in the through-holes provided in the conductive layer 31e and electrically connected thereto. The pins 45a to 45d have bottom ends bonded to corresponding gate electrodes 6b of the semiconductor chips 63a to 63d via a bonding material (not illustrated) such as solder or a sintered material and electrically connected thereto. The control terminal 45 extending vertically is fitted by pressing in another through-hole provided in the conductive layer 31e and electrically connected thereto.

The conductive layer 31f has a U-shaped plane pattern to surround the conductive layer 31e. The pins 46a to 46d extending vertically are fitted by pressing in the through-holes provided in the conductive layer 31f and electrically connected thereto. The pins 46a to 46d have bottom ends bonded to corresponding source electrodes 6a of the semiconductor chips 63a to 63d via a bonding material (not illustrated) such as solder or a sintered material and electrically connected thereto. The control terminal 46 extending vertically is fitted by pressing in another through-hole provided in the conductive layer 31h and electrically connected thereto.

The pins 47a to 47d extending vertically are fitted by pressing in the through-holes provided in the conductive layer 31g and electrically connected thereto. The pins 47a to 47d have bottom ends bonded to corresponding gate electrodes 6b of the semiconductor chips 64a to 64d via a bonding material (not illustrated) such as solder or a sintered material and electrically connected thereto. The control terminal 47 extending vertically is fitted by pressing in another through-hole provided in the conductive layer 31g and electrically connected thereto.

The conductive layer 31h has a U-shaped plane pattern to surround the conductive layer 31g. The pins 48a to 48d extending vertically are fitted by pressing in the through-holes provided in the conductive layer 31h and electrically connected thereto. The pins 48a to 48d have bottom ends bonded to corresponding source electrodes 6a of the semiconductor chips 64a to 64d via a bonding material (not illustrated) such as solder or a sintered material and electrically connected thereto. The control terminal 48 extending vertically is fitted by pressing in another through-hole provided in the conductive layer 31h and electrically connected thereto.

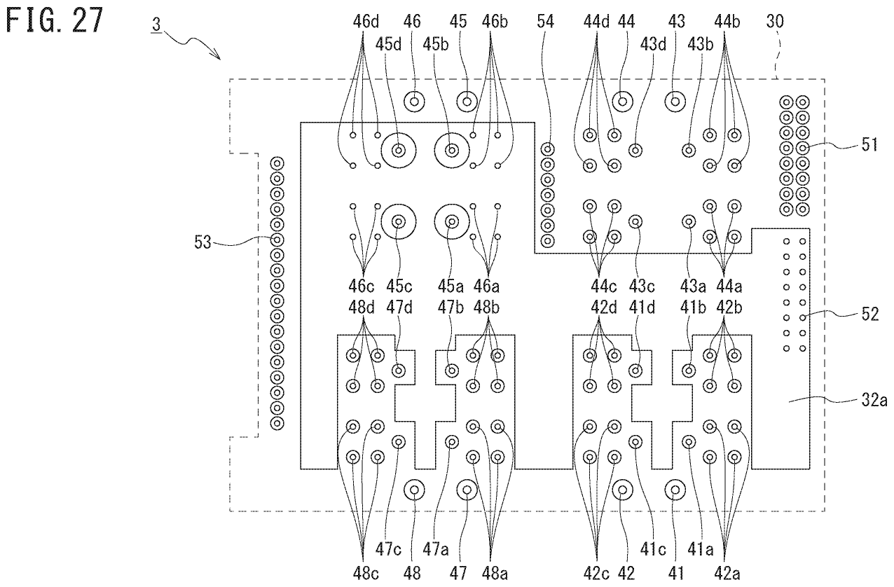

FIG. 27 is a plan view illustrating the conductive layer 32a as the second layer from the top inside the wiring board 3 in an extracted manner. In FIG. 27, the external shape of the insulating layer 30 around the conductive layers 32a is schematically illustrated by a broken line. The conductive layer 32a faces the conductive layers 31a to 31h illustrated in FIG. 26 via the insulating layer 30, the conductive layers 31a to 31h being above the conductive layer 32a. The conductive layer 32a has through-holes. The pins 45a to 45d extending vertically pass through the through-holes provided in the conductive layer 32a, with a clearance. The pins 46a to 46d, 52 extending vertically are fitted by pressing in other through-holes provided in the conductive layer 32a and electrically connected thereto. The pins 52 have bottom ends bonded to the conductive plate 15 via a bonding material (not illustrated) such as solder or a sintered material and electrically connected thereto.

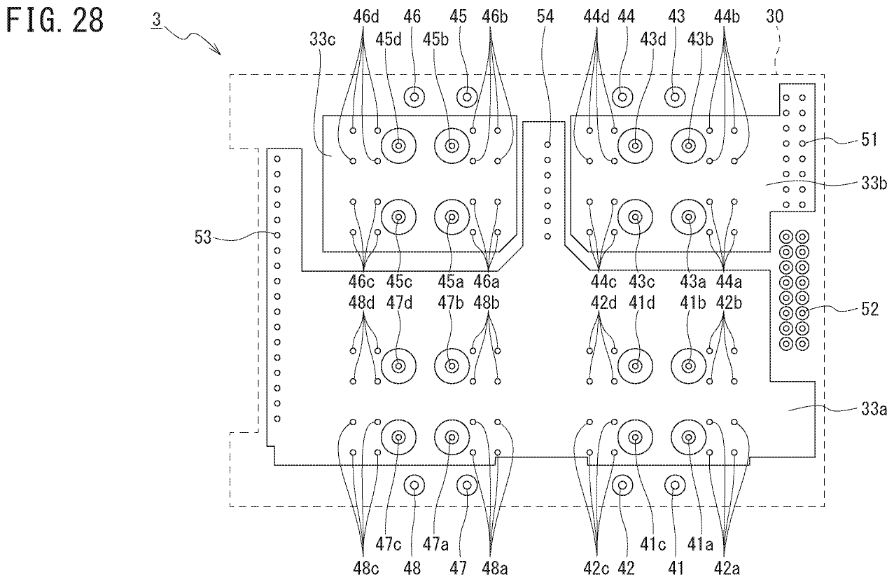

FIG. 28 is a plan view illustrating the conductive layers 33a to 33c as the lowermost layer, which is the third layer from the top inside the wiring board 3, in an extracted manner. In FIG. 28, the external shape of the insulating layer 30 around the conductive layers 33a to 33c is schematically illustrated by a broken line. The conductive layers 33a to 33c face the conductive layer 32a illustrated in FIG. 27 via the insulating layer 30, the conductive layer 32a being above the conductive layers 33a to 33c. The conductive layers 33a to 33c have through-holes.

The pins 41a to 41d, 47a to 47d extending vertically pass through the through-holes provided in the conductive layer 33a, with a clearance. The pins 42a to 42d, 48a to 48d, 53, 54 extending vertically are fitted by pressing in other through-holes provided in the conductive layer 33a and electrically connected thereto. The pins 53 have bottom ends bonded to the conductive plate 16 via a bonding material (not illustrated) such as solder or a sintered material and electrically connected thereto. The pins 54 have bottom ends bonded to the the conductive plate 12 via a bonding material (not illustrated) such as solder or a sintered material and electrically connected thereto.

The pins 43a to 43d extending vertically pass through the through-holes provided in the conductive layer 33b, with a clearance. The pins 44a to 44d, 51 extending vertically are fitted by pressing in another through-hole provided in the conductive layer 33b and electrically connected thereto. The pins 51 have bottom ends bonded to the conductive plate 14 via a bonding material (not illustrated) such as solder or a sintered material and electrically connected thereto.

The pins 45a to 45d extending vertically pass through the through-holes provided in the conductive layer 33c, with a clearance. The pins 46a to 46d extending vertically are fitted by pressing in other through-holes provided in the conductive layer 33c and electrically connected thereto.

Note that the above description has described the wiring board 3 having a three-layer structure including the conductive layers 31a to 31d as the first layer from the top of the wiring board 3 as illustrated in FIG. 26, the conductive layer 32a as the second layer from the top of the wiring board 3 as illustrated in FIG. 27, and the conductive layers 33a to 33c as the third layer from the top of the wiring board 3 as illustrated in FIG. 28. However, the order of the layers is not particularly limited and may be changed. Alternatively, the wiring board 3 may have a multilayer structure including four or more layers further including other conductive layers in addition to the three layers.

In the semiconductor device according to the fourth embodiment, the current path from the positive terminal 21 to the negative terminal 22 starts from the positive terminal 21 illustrated in FIG. 25 and reaches the negative terminal 22 via the conductive plate 11, the semiconductor chips 61a to 61d from the drain electrodes on the bottom surface sides thereof to the source electrodes 6a on the top surface sides thereof, the pins 42a to 42d, the conductive layer 33a, and the pins 54 illustrated in FIG. 28, the conductive plate 12 and the semiconductor chips 62a to 62d from the drain electrodes on the bottom surface sides thereof to the source electrodes 6a on the top surface sides thereof, illustrated in FIG. 25, the pins 44a to 44d and the conductive layer 33b, and the pins 51 illustrated in FIG. 28, and the conductive plate 14 illustrated in FIG. 25.

In the semiconductor device according to the fourth embodiment, the current path from the positive terminal 21 to the intermediate terminal 23 starts from the positive terminal 21 illustrated in FIG. 25 and reaches the intermediate terminal 23 via the conductive plate 11, the semiconductor chips 61a to 61d from the drain electrodes on the bottom surface sides thereof to the source electrodes 6a on the top surface sides thereof, the pins 42a to 42d, the conductive layer 33a, and the pins 48a to 48d illustrated in FIG. 28, the semiconductor chips 64a to 64d from the source electrodes 6a on the top surface sides thereof to the drain electrodes on the bottom surface sides thereof, the conductive plate 13, and the semiconductor chips 63a to 63d from the drain electrodes on the bottom surface sides thereof to the source electrodes 6a on the top surface sides thereof, illustrated in FIG. 25, the pins 46a to 46d, the conductive layer 32a, and the pins 52 illustrated in FIG. 27, and the conductive plate 15 illustrated in FIG. 25.

In the semiconductor device according to the fourth embodiment, the current path from the negative terminal 22 to the intermediate terminal 23 starts from the negative terminal 22 illustrated in FIG. 25 and reaches the intermediate terminal 23 via the conductive plate 14, the pins 51, the conductive layer 33b, and the pins 44a to 44d illustrated in FIG. 28, the semiconductor chips 62a to 62d from the source electrodes 6a on the top surface sides thereof to the drain electrodes on the bottom surface sides thereof and the conductive plate 12 illustrated in FIG. 25, the pins 54, the conductive layer 33a, and the pins 48a to 48d illustrated in FIG. 28, the semiconductor chips 64a to 64d from the source electrodes 6a on the top surface sides thereof to the drain electrodes on the bottom surface sides thereof, the conductive plate 13, and the semiconductor chips 63a to 63d from the drain electrodes on the bottom surface sides thereof to the source electrodes 6a on the top surface sides thereof, illustrated in FIG. 25, the pins 46a to 46d, the conductive layer 32a, and the pins 52 illustrated in FIG. 27, and the conductive plate 15 illustrated in FIG. 25.

The other configuration of the semiconductor device according to the fourth embodiment is substantially the same as that of the semiconductor device according to the first embodiment, and descriptions thereof are omitted.

In the semiconductor device according to the fourth embodiment, the semiconductor chips 61a to 61d and the semiconductor chips 62a to 62d are provided on the side where the positive terminal 21, the negative terminal 22, and the intermediate terminal 23 are provided, thereby making it possible to shorten the current path and to reduce the inductance between the positive terminal 21 and the negative terminal 22. Besides, in the semiconductor device according to the fourth embodiment, the effect of mutual inductance is achieved due to the three-dimensional wiring layout using the wiring board 3. This makes it possible to reduce the inductance between the positive terminal 21 and the intermediate terminal 23 and the inductance between the intermediate terminal 23 and the negative terminal 22. Besides, in the semiconductor device according to the fourth embodiment, the module can be reduced in size due to the three-dimensional wiring using the wiring board 3.

### Other Embodiments

The first to forth embodiments of this disclosure have been described above, but it should be understood that the description and the drawings as part of this disclosure do not restrict this disclosure. Various alternative embodiments, examples, and operational technologies will become clear to a person skilled in the art from this disclosure.

For example, in the first to fourth embodiments, the positive terminal 21 and the negative terminal 22 may be disposed in reverse (for example, upside down relative to FIG. 3). In this case, the conductive plates 11 to 17, the semiconductor chips 60, 61 to 64, 61a to 61d, 62a to 62d, 63a to 63d, 64a to 64d, and the conductive layers of the wiring board 3 should be also disposed in reverse.

The configurations disclosed in the first to fourth embodiments can be combined appropriately as far as no consistency occurs. It is needless to say that this disclosure includes various embodiments and so on that are not described herein. Accordingly, the technical scope of this disclosure is determined only by the invention specification matter according to appropriate claims from the above description.

1. A semiconductor device, comprising:
first to fourth semiconductor chips;
a first conductive plate electrically connected to a bottom surface of the first semiconductor chip;
a second conductive plate electrically connected to a bottom surface of the second semiconductor chip;
a third conductive plate electrically connected to a bottom surface of each of the third and fourth semiconductor chips;
a first external terminal connected to the first conductive plate;
a second external terminal electrically connected to a top surface of the second semiconductor chip;
a third external terminal electrically connected to a top surface of the third semiconductor chip; and
a fourth external terminal electrically connected to a top surface of each of the first and fourth semiconductor chips, wherein
the first to third external terminals are disposed to be opposite to the fourth external terminal across the first to fourth semiconductor chips, and
the first and second semiconductor chips are provided closer to the first and second external terminals than the third and fourth semiconductor chips.

2. The semiconductor device according to claim 1, further comprising:
a wiring board including
a first conductive layer electrically connecting the second conductive plate to the top surface of each of the first and fourth semiconductor chips,
a second conductive layer electrically connected to the top surface of the second semiconductor chip and the second external terminal,
a third conductive layer electrically connected to the top surface of the third semiconductor chip and the third external terminal, and
an insulating layer disposed between the first conductive layer and the third conductive layer.

3. The semiconductor device according to claim 2, wherein the first to fourth semiconductor chips are electrically connected to the wiring board by at least one selected from pins, bumps, and solder.

4. The semiconductor device according to claim 2, wherein
the third conductive layer includes a plurality of third conductive layers, and
the first conductive layer is disposed between the third conductive layers via the insulating layer.

5. The semiconductor device according to claim 2, wherein the first to fourth semiconductor chips are disposed in a matrix form, the first semiconductor chip is disposed diagonally to the fourth semiconductor chip, and the second semiconductor chip is disposed diagonally to the third semiconductor chip.

6. The semiconductor device according to claim 5, wherein each of the first to fourth semiconductor chips includes a plurality of semiconductor chips disposed to form a plurality of columns arranged side by side in a direction where the first to third external terminals are opposed to the fourth external terminal.

7. The semiconductor device according to claim 6, wherein the first to fourth semiconductor chips includes gate electrodes on top surfaces of the first to fourth semiconductor chips respectively, and the respective gate electrodes are disposed to face inward between the plurality of columns.

8. The semiconductor device according to claim 7, wherein
the wiring board includes a plurality of gate wiring foils electrically connected to the gate electrodes of the first to fourth semiconductor chips respectively, and
the gate wiring foils are electrically connected to the gate electrodes of the first to fourth semiconductor chips respectively by at least one selected from pins, bumps, and solder.

9. The semiconductor device according to claim 8, wherein
the wiring board includes a plurality of auxiliary control wiring foils electrically connected to the top surfaces of the first to fourth semiconductor chips respectively, and
the auxiliary control wiring foils are electrically connected to the top surfaces of the first to fourth semiconductor chips respectively by at least one selected from pins, bumps, and solder.

10. The semiconductor device according to claim 9, wherein the auxiliary control wiring foils surrounds the gate wiring foils in a U-shape.

11. The semiconductor device according to claim 9, wherein the gate wiring foils and the auxiliary control wiring foils are provided on a top surface side of the wiring board relative to the first conductive layer, the second conductive layer, and the third conductive layer.

12. The semiconductor device according to claim 1, wherein the first to fourth semiconductor chips are disposed in a matrix form, the first semiconductor chip is disposed diagonally to the third semiconductor chip, and the second semiconductor chip is disposed diagonally to the fourth semiconductor chip.

13. The semiconductor device according to claim 1, wherein
the second conductive plate is electrically connected to each of the top surfaces of the first and fourth semiconductor chips by a wire,
the top surface of the second semiconductor chip is electrically connected to the second external terminal by a wire, and
the top surface of the third semiconductor chip is electrically connected to the third external terminal by a wire.

14. The semiconductor device according to claim 1, wherein the first and second semiconductor chips are provided closer to the third external terminal than the third and fourth semiconductor chips.
